(19) United States
(12) Patent Application Publication
(10) Pub. No.: US 2024/0351861 A1
(43) Pub. Date: Oct. 24, 2024

(54) ELECTROCHEMICAL REDUCTION OF CARBON DIOXIDE

(71) Applicant: JAPAN SCIENCE AND TECHNOLOGY AGENCY, Kawaguchi-shi (JP)

(72) Inventor: Osamu ISHITANI, Meguro-ku (JP)

(73) Assignee: JAPAN SCIENCE AND TECHNOLOGY AGENCY, Kawaguchi-shi (JP)

(21) Appl. No.: 18/751,503

(22) Filed: Jun. 24, 2024

Related U.S. Application Data
(63) Continuation of application No. 17/817,367, filed on Aug. 4, 2022, now Pat. No. 11,772,962.
Application No. 17/817,367 is a continuation of application No. 16/887,389, filed on May 29, 2020, now abandoned.
Application No. 16/887,389 is a continuation of application No. 15/553,739, filed on Aug. 25, 2017, now abandoned.

(30) Foreign Application Priority Data
Feb. 27, 2015 (JP) 2015-037839
Aug. 18, 2015 (JP) 2015-160768

(51) Int. Cl. B81B 7/00; B81C 1/00

(52) U.S. Cl. CPC B81B 7/0058; B81C 1/00333; B81B 2207/07

(57) ABSTRACT

Disclosed herein is an electrochemical cell and a production system for selectively reducing, using electrical energy, CO₂ to carbon monoxide or formic acid, a catalyst for use in the method, and an electrochemical reduction system. The method for producing carbon monoxide or formic acid by electrochemically reducing carbon dioxide of the present invention includes (a) reacting carbon dioxide with a metal complex represented by formula (1), and (b) applying a voltage to a reaction product of the carbon dioxide and the metal complex represented by formula (1):

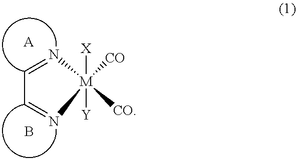

### CROSS REFERENCE TO RELATED APPLICATIONS

This application is a continuation application of prior U.S. application Ser. No. 17/818,367, filed Aug. 9, 2022, the disclosure of which is incorporated herein by reference in its entirety. U.S. application Ser. No. 17/818,367 is a continuation application of prior U.S. application Ser. No. 16/887,389, filed May 29, 2020, now abandoned, the disclosure of which is incorporated herein by reference in its entirety. U.S. application Ser. No. 16/887,389 is a continuation application of prior U.S. application Ser. No. 15/553,739, filed Aug. 25, 2017, now abandoned, the disclosure of which is incorporated herein by reference in its entirety. U.S. application Ser. No. 15/553,739 is the National Stage of PCT/JP2016/053558, filed Feb. 5, 2016, the disclosure of which is incorporated herein by reference in its entirety. U.S. application Ser. No. 15/553,739 claims priority to Japanese Application No. 2015-037839, filed Feb. 27, 2015, and Japanese Application No. 2015-160768, filed Aug. 18, 2015, the disclosures of which are incorporated herein by reference in their entireties.

### TECHNICAL FIELD

The present invention relates to a method for electrochemically reducing carbon dioxide to carbon monoxide or formic acid, and relates to a catalyst used therefor.

### BACKGROUND ART

Currently, people are facing serious problems of global warming and exhaustion of carbon resources. As means for solving these problems, a catalyst for converting light energy into chemical energy is attracting attention. It is expected that these problems should be solved all at once if carbon dioxide (CO₂) could be converted into a useful compound using inexhaustible solar energy. CO₂ is, however, an end product of oxidation of carbon compounds, and hence is both physically and chemically very stable and has very low reactivity.

Recently, some techniques for converting CO₂ into a useful compound through reduction have been reported. For example, Patent Literature 1 describes a method for obtaining formic acid by reacting CO₂ and hydrogen in the presence of a catalyst, and Patent Literature 2 describes a method for obtaining formic acid through reduction of CO₂ caused by transferring, to a catalyst, an excited electron generated through light irradiation of a semiconductor electrode. Besides, Patent Literature 3 and Non Patent Literature 1 have reported a method for reducing CO₂ to carbon monoxide by bringing a rhenium complex into contact with CO₂ and irradiating the resultant with light. Furthermore, attempts have been made to electrochemically reducing CO₂ in the presence of a metal complex catalyst (Patent Literature 4).

### CITATION LIST

### Patent Literature

[Patent Literature 1] JP-A-2004-217632
[Patent Literature 2] JP-A-2011-82144
[Patent Literature 3] JP-A-2013-180943
[Patent Literature 4] JP-A-2013-193056

### Non Patent Literature

[Non Patent Literature 1] J. Am. Chem. Soc. 2013, 135, 16825-16828

### SUMMARY OF INVENTION

### Technical Problem

The methods described in Patent Literatures 1 and 2 require, however, hydrogen or a semiconductor and light irradiation for the reduction, and in addition, hydrogen is necessary for the reduction in Patent Literature 1, and thus these methods cannot be said energetically advantageous. Besides, in Patent Literature 3 and Non Patent Literature 1, another catalyst such as a ruthenium complex is necessary for a photocatalytic reaction in addition to a reduction catalyst. Furthermore, in Patent Literature 4, a product resulting from the electrochemical treatment of CO₂ is unknown.

On the other hand, if carbon monoxide (CO) or formic acid can be selectively obtained through the reduction of CO₂, the thus obtained carbon monoxide can be a material of extremely various hydrocarbons. A hydrocarbon is a chemical energy material similarly to petroleum. Besides, formic acid can be used for easily producing hydrogen through a reaction with a catalyst, and hence is expected as a liquid fuel which stores hydrogen.

Accordingly, an object of the present invention is to provide a method for reducing CO₂ selectively to carbon monoxide or formic acid by using electrical energy, a catalyst for use in the method, and an electrochemical reduction system.

### Solution to Problem

Therefore, the present inventor made various examinations for electrochemically performing reduction of CO₂ to carbon monoxide or formic acid, and found that CO₂ can be selectively and easily reduced to carbon monoxide or formic acid by reacting CO₂ with a metal complex represented by formula (1) or formula (2) and applying a voltage to the resultant reaction product, and that this reduction reaction proceeds even if the concentration of CO₂ to be introduced is low, resulting in accomplishing the present invention.

Specifically, the present invention provides the following [1] to [30]:

[1] A method for producing carbon monoxide by electrochemically reducing carbon dioxide, comprising the following steps (a) and (b):
(a) reacting carbon dioxide with a metal complex represented by formula (1):

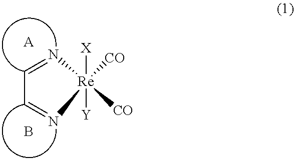

wherein
X represents OR¹, SR¹, NR²R³R⁴ or PX¹X²X³,
Y represents CO, OR¹, SR¹, NR²R³R⁴ or PX¹X²X³,
ring A and ring B are identical or different and represent a nitrogen atom-containing heterocycle optionally having a substituent,
R¹ represents a hydrocarbon group optionally having a substituent,
one, two or three of R², R³ and R⁴ are identical or different and represent a hydrocarbon group optionally having a substituent, the rest representing a hydrogen atom, and
one, two or three of X¹, X² and X³ are identical or different and represent a hydrocarbon group optionally having a substituent or a hydrocarbon oxy group optionally having a substituent, the rest representing a hydrogen atom or a hydroxy group; and
(b) applying a voltage to a reaction product of the carbon dioxide and the metal complex represented by formula (1).

[2] The production method according to [1], wherein the aforementioned steps (a) and (b) are performed within an electrochemical cell including a working electrode and a counter electrode, and the method comprises the following steps (a1) and (b1):
(a1) introducing carbon dioxide into a solution containing the metal complex held in the electrochemical cell; and
(b1) applying a negative voltage and a positive voltage respectively to the working electrode and the counter electrode of the electrochemical cell.

[3] The production method according to [2], wherein the carbon dioxide is introduced by introducing a carbon dioxide-containing gas into the solution containing the metal complex.

[4] The production method according to any one of [1] to [3], wherein the carbon dioxide to be reacted is a gas containing 0.03 to 100% of carbon dioxide.

[5] The production method according to any one of [1] to [4], wherein the nitrogen atom-containing heterocycle including ring A and ring B is a heterocycle having a 2,2′-bipyridine structure optionally having a substituent.

[6] The production method according to any one of [1] to [5], wherein each hydrocarbon group optionally having a substituent represented by R¹, R², R³, R⁴, X¹, X² and X³ is one selected from the group consisting of an alkyl group, an alkenyl group, a cycloalkyl group, a cycloalkenyl group and an aromatic hydrocarbon group, each of which optionally has one to three substituents selected from the group consisting of a primary, secondary or tertiary amino group, a hydroxy group, an alkoxy group, an aryloxy group, a halogen atom, a nitro group, a cyano group, a formyl group, an alkanoyl group and an arylcarbonyl group.

[7] A method for producing carbon monoxide from carbon dioxide, wherein the carbon monoxide obtained by the production method according to any one of [1] to [6] is used as a reducing agent.

[8] A method for producing a hydrocarbon-based compound, wherein the carbon monoxide obtained by the production method according to any one of [1] to [6] is used as a raw material.

[9] A catalyst for electrochemically reducing carbon dioxide to carbon monoxide, represented by formula (1):

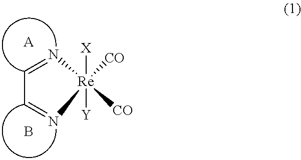

wherein
X represents OR¹, SR¹, NR²R³R⁴ or PX¹X²X³,
Y represents CO, OR¹, SR¹, NR²R³R⁴ or PX¹X²X³,
ring A and ring B are identical or different and represent a nitrogen atom-containing heterocycle optionally having a substituent,
R¹ represents a hydrocarbon group optionally having a substituent,
one, two or three of R², R³ and R⁴ are identical or different and represent a hydrocarbon group optionally having a substituent, the rest representing a hydrogen atom, and
one, two or three of X¹, X² and X³ are identical or different and represent a hydrocarbon group optionally having a substituent or a hydrocarbon oxy group optionally having a substituent, the rest representing a hydrogen atom or a hydroxy group.

[10] The catalyst according to [9], wherein the nitrogen atom-containing heterocycle including ring A and ring B is a heterocycle having a 2,2′-bipyridine structure optionally having a substituent.

[11] The catalyst according to [9] or [10], wherein each hydrocarbon group optionally having a substituent represented by R¹, R², R³, R⁴, X¹, X² and X³ is one selected from the group consisting of an alkyl group, an alkenyl group, a cycloalkyl group, a cycloalkenyl group and an aromatic hydrocarbon group, each of which optionally has one to three substituents selected from the group consisting of a primary, secondary or tertiary amino group, a hydroxy group, an alkoxy group, an aryloxy group, a halogen atom, a nitro group, a cyano group, a formyl group, an alkanoyl group and an arylcarbonyl group.

[12] A method for producing formic acid by electrochemically reducing carbon dioxide, comprising the following steps (a) and (b):
(a) reacting carbon dioxide with a metal complex represented by formula (2):

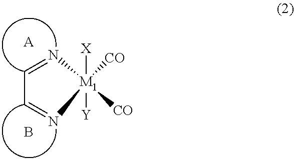

wherein
M₁ represents manganese, ruthenium or iron,
X represents OR¹, SR¹, NR²R³R⁴ or PX¹X²X³,
Y represents CO, OR¹, SR¹, NR²R³R⁴ or PX¹X²X³,
ring A and ring B are identical or different and represent a nitrogen atom-containing heterocycle optionally having a substituent,
R¹ represents a hydrocarbon group optionally having a substituent,
one, two or three of R², R³ and R⁴ are identical or different and represent a hydrocarbon group optionally having a substituent, the rest representing a hydrogen atom, and
one, two or three of X¹, X² and X³ are identical or different and represent a hydrocarbon group optionally having a substituent or a hydrocarbon oxy group optionally having a substituent, the rest representing a hydrogen atom or a hydroxy group; and
(b) applying a voltage to a reaction product of the carbon dioxide and the metal complex represented by formula (2).

[13] The production method according to [12], wherein the aforementioned steps (a) and (b) are performed within an electrochemical cell including a working electrode and a counter electrode, and the method comprises the following steps (a1) and (b1):
(a1) introducing carbon dioxide into a solution containing the metal complex held in the electrochemical cell; and
(b1) applying a negative voltage and a positive voltage respectively to the working electrode and the counter electrode of the electrochemical cell.

[14] The production method according to [13], wherein the carbon dioxide is introduced by introducing a carbon dioxide-containing gas into the solution containing the metal complex.

[15] The production method according to any one of [12] to [14], wherein the carbon dioxide to be reacted is a gas containing 0.03 to 100% of carbon dioxide.

[16] The production method according to any one of [12] to [15], wherein the nitrogen atom-containing heterocycle including ring A and ring B is a heterocycle having a 2,2′-bipyridine structure optionally having a substituent.

[17] The production method according to any one of [12] to [16], wherein each hydrocarbon group optionally having a substituent represented by R¹, R², R³, R⁴, X¹, X² and X³ is one selected from the group consisting of an alkyl group, an alkenyl group, a cycloalkyl group, a cycloalkenyl group and an aromatic hydrocarbon group, each of which optionally has one to three substituents selected from the group consisting of a primary, secondary or tertiary amino group, a hydroxy group, an alkoxy group, an aryloxy group, a halogen atom, a nitro group, a cyano group, a formyl group, an alkanoyl group and an arylcarbonyl group.

[18] A catalyst for electrochemically reducing carbon dioxide to formic acid, represented by formula (2):

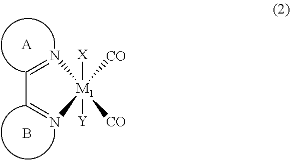

wherein
M₁ represents manganese, ruthenium or iron,
X represents OR¹, SR¹, NR²R³R⁴ or PX¹X²X³,
Y represents CO, OR¹, SR¹, NR²R³R⁴ or PX¹X²X³,
ring A and ring B are identical or different and represent a nitrogen atom-containing heterocycle optionally having a substituent,
R¹ represents a hydrocarbon group optionally having a substituent,
one, two or three of R², R³ and R⁴ are identical or different and represent a hydrocarbon group optionally having a substituent, the rest representing a hydrogen atom, and
one, two or three of X¹, X² and X³ are identical or different and represent a hydrocarbon group optionally having a substituent or a hydrocarbon oxy group optionally having a substituent, the rest representing a hydrogen atom or a hydroxy group.

[19] The catalyst according to [18], wherein the nitrogen atom-containing heterocycle including ring A and ring B is a heterocycle having a 2,2′-bipyridine structure optionally having a substituent.

[20] The catalyst according to [18] or [19], wherein each hydrocarbon group optionally having a substituent represented by R¹, R², R³, R⁴, X¹, X² and X³ is one selected from the group consisting of an alkyl group, an alkenyl group, a cycloalkyl group, a cycloalkenyl group and an aromatic hydrocarbon group, each of which optionally has one to three substituents selected from the group consisting of a primary, secondary or tertiary amino group, a hydroxy group, an alkoxy group, an aryloxy group, a halogen atom, a nitro group, a cyano group, a formyl group, an alkanoyl group and an arylcarbonyl group.

[21] A metal complex represented by formula (2a):

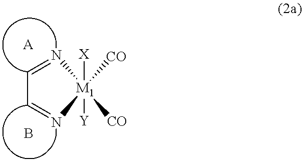

wherein
M₁ represents manganese, ruthenium or iron,
X represents O(CH₂)ₙNR⁵R⁶, NR⁵R⁶ or PX¹X²X³,
Y represents CO, O(CH₂)ₙNR⁵R⁶, NR⁵R⁶ or PX¹X²X³,
ring A and ring B are identical or different and represent a nitrogen atom-containing heterocycle optionally having a substituent,
one, two or three of X¹, X² and X³ are identical or different and represent a hydrocarbon group optionally having a substituent or a hydrocarbon oxy group optionally having a substituent, the rest representing a hydrogen atom or a hydroxy group,
R⁵ and R⁶ are identical or different and represent an alkyl group, a hydroxyalkyl group or a hydrogen atom, and
n represents a number of 2 to 8.

[22] The metal complex according to [21], wherein the nitrogen atom-containing heterocycle including ring A and ring B is a heterocycle having a 2,2′-bipyridine structure optionally having a substituent.

[23] The metal complex according to [21] or [22], wherein each hydrocarbon group optionally having a substituent represented by X¹, X² and X³ is one selected from the group consisting of an alkyl group, an alkenyl group, a cycloalkyl group, a cycloalkenyl group and an aromatic hydrocarbon group, each of which optionally has one to three substituents selected from the group consisting of a primary, secondary or tertiary amino group, a hydroxy group, an alkoxy group, an aryloxy group, a halogen atom, a nitro group, a cyano group, a formyl group, an alkanoyl group and an arylcarbonyl group.

[24] A carbon monoxide production system for producing carbon monoxide by electrochemically reducing carbon dioxide, the carbon monoxide production system comprising:
an electrochemical cell part equipped with a solution containing a metal complex, a working electrode and a counter electrode;
an injection part through which carbon dioxide is injected into the solution containing the metal complex held in the electrochemical cell part;
a voltage source capable of applying a positive or negative voltage between the working electrode and the counter electrode of the electrochemical cell part; and
a discharge part discharging carbon monoxide generated within the solution containing the metal complex, wherein the carbon monoxide is generated by applying a positive or negative voltage to a reaction product of the metal complex generated by the solution containing the metal complex and the carbon dioxide.

[25] The carbon monoxide production system according to [24],
wherein the metal complex is represented by formula (1):

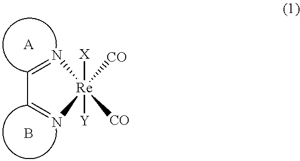

wherein
X represents OR¹, SR¹, NR²R³R⁴ or PX¹X²X³,
Y represents CO, OR¹, SR¹, NR²R³R⁴ or PX¹X²X³,
ring A and ring B are identical or different and represent a nitrogen atom-containing heterocycle optionally having a substituent,
R¹ represents a hydrocarbon group optionally having a substituent,
one, two or three of R², R³ and R⁴ are identical or different and represent a hydrocarbon group optionally having a substituent, the rest representing a hydrogen atom, and
one, two or three of X¹, X² and X³ are identical or different and represent a hydrocarbon group optionally having a substituent or a hydrocarbon oxy group optionally having a substituent, the rest representing a hydrogen atom or a hydroxy group.

[26] The carbon monoxide production system according to [24] or [25], wherein the carbon dioxide is fed without concentration in a feed part feeding the carbon dioxide.

[27] The carbon monoxide production system according to any one of [24] to [26], further comprising a carbon monoxide detection part detecting a concentration of the carbon monoxide discharged from the solution containing the metal complex.

[28] The carbon monoxide production system according to [27], wherein the carbon monoxide detection part is a gas chromatography.

[29] The carbon monoxide production system according to any one of [24] to [28], wherein the nitrogen atom-containing heterocycle including ring A and ring B is a heterocycle having a 2,2′-bipyridine structure optionally having a substituent.

[30] The carbon monoxide production system according to any one of [24] to [29], wherein each hydrocarbon group optionally having a substituent represented by R¹, R², R³, R⁴, X¹, X² and X³ is one selected from the group consisting of an alkyl group, an alkenyl group, a cycloalkyl group, a cycloalkenyl group and an aromatic hydrocarbon group, each of which optionally has one to three substituents selected from the group consisting of a primary, secondary or tertiary amino group, a hydroxy group, an alkoxy group, an aryloxy group, a halogen atom, a nitro group, a cyano group, a formyl group, an alkanoyl group and an arylcarbonyl group.

### Effects of Invention

If a catalyst of the present invention and an electrochemical treatment are employed, carbon monoxide (CO) or formic acid can be efficiently produced from CO₂ by simple means even if the CO₂ is at a low concentration. Accordingly, carbon monoxide or formic acid which can be various chemical materials can be efficiently produced from a CO₂-containing waste gas of facilities, such as a thermal power station or an ironworks, in which a combustion waste gas of an organic matter including petroleum is generated. Accordingly, carbon monoxide or formic acid which can be a raw material of a useful and energy-storing chemical substance such as hydrocarbon or hydrogen can be produced from a combustion waste gas of a fossil fuel such as petroleum, coal or natural gas, and therefore, contribution can be made to both energy reuse and CO₂ emission reduction.

### BRIEF DESCRIPTION OF DRAWINGS

FIG. 1 is a conceptual diagram of a carbon monoxide production system of the present invention.

FIG. 2 is a conceptual diagram of an example of a reaction-side cell chamber of the carbon monoxide production system of the present invention. Like reference signs are used in this drawing to refer to like elements of FIG. 1.

FIG. 3 illustrates IR spectrum change (solvent: DMF-TEOA (5:1 v/v)) obtained by allowing CO₂ to pass for 30 minutes through a solution 4 hours after adding TEOA. Spectrum obtained before the passage: gray line, spectrum obtained after the passage: black line

FIG. 4 illustrates IR spectrum change (solvent: DMF-TEOA (5:1 v/v)) obtained by allowing Ar to pass through the solution after allowing the CO₂ to pass (after 0 to 120 minutes).

FIG. 5 illustrates an ESI-MS spectrum (solvent: MeCN) of a DMF-TEOA mixed solution (5:1 v/v) containing Re—CO₂-TEOA.

FIG. 6 illustrates IR spectra (black solid lines) obtained after passage of the ambient air and curve fitting curves. (Peaks corresponding to a complex in which DMF is coordinated, a complex in which —O—CO—OCH₂CH₂NR₂ (R=CH₂CH₂OH) is coordinated, and a complex in which TEOA is coordinated, arranged in this order from a right peak illustrated with a dotted line. A gray solid line is formed by adding up these three peaks.) Substituents in 4,4′-position: (a) hydrogen, (b) a methyl group, (c) a methoxy group, and (d) a bromo group

FIG. 7 illustrates amount of CO generated and current change obtained in electrochemical CO₂ reduction experiment using Re—CO₂-TEOA as a catalyst.

FIG. 8 illustrates amount of CO generated and current change obtained by adding TEOA.

FIG. 9 illustrates measurement results of cyclic voltammetry (CV) of a Re complex performed for setting an application voltage. In this drawing, “baseline” corresponds to a measurement result obtained without the complex under CO₂ atmosphere, “under Ar” corresponds to a measurement result obtained with or without the complex under Ar atmosphere, and “under CO₂” corresponds to a measurement result obtained with or without the complex under CO₂ atmosphere.

FIG. 10 illustrates measurement results of the cyclic voltammetry (CV) of a Mn complex performed for setting an application voltage. A dotted line corresponds to a result obtained under Ar atmosphere. A solid line corresponds to a result obtained under CO₂ atmosphere.

FIG. 11 illustrates current value change obtained in an electrochemical CO₂ reduction experiment using Mn—CO₂-TEOA as a catalyst.

FIG. 12 illustrates amount of CO generated obtained in the electrochemical CO₂ reduction experiment using Mn—CO₂-TEOA as a catalyst.

FIG. 13 illustrates IR spectra of various manganese triethanolamine adduct complexes with a CO₂ concentration of 10%.

FIG. 14 illustrates IR spectrum change obtained in DMF-DEOA of a Mn complex under atmosphere of various CO₂ concentrations.

FIG. 15 illustrates measurement results of the cyclic voltammetry (CV) of a Mn complex in DMF-DEOA under CO₂ atmosphere performed for setting an application voltage.

FIG. 16 illustrates amount of formic acid generated and current value change obtained in an electrochemical CO₂ reduction experiment using Mn—CO₂-DEOA as a catalyst.

### DESCRIPTION OF EMBODIMENT

A catalyst used in electrochemical reduction of CO₂ to CO of the present invention is a metal complex represented by formula (1):

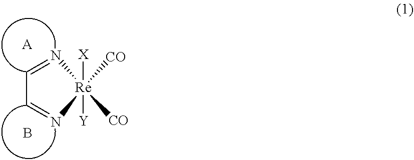

wherein
X represents OR¹, SR¹, NR²R³R⁴ or PX¹X²X³;
Y represents CO, OR¹, SR¹, NR²R³R⁴ or PX¹X²X³;
ring A and ring B are identical or different and represent a nitrogen atom-containing heterocycle optionally having a substituent;
R¹ represents a hydrocarbon group optionally having a substituent;
one, two or three of R², R³ and R⁴ are identical or different and represent a hydrocarbon group optionally having a substituent, the rest representing a hydrogen atom; and
one, two or three of X¹, X² and X³ are identical or different and represent a hydrocarbon group optionally having a substituent or a hydrocarbon oxy group optionally having a substituent, the rest representing a hydrogen atom or a hydroxy group.

On the other hand, a catalyst used in electrochemical reduction of CO₂ to formic acid of the present invention is a metal complex represented by formula (2):

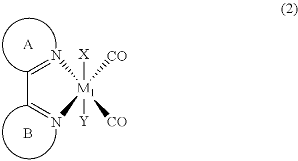

wherein
M₁ represents manganese, ruthenium or iron;
X represents OR¹, SR¹, NR²R³R⁴ or PX¹X²X³;
Y represents CO, OR¹, SR¹, NR²R³R⁴ or PX¹X²X³;
ring A and ring B are identical or different and represent a nitrogen atom-containing heterocycle optionally having a substituent;
R¹ represents a hydrocarbon group optionally having a substituent;
one, two or three of R², R³ and R⁴ are identical or different and represent a hydrocarbon group optionally having a substituent, the rest representing a hydrogen atom; and
one, two or three of X¹, X² and X³ are identical or different and represent a hydrocarbon group optionally having a substituent or a hydrocarbon oxy group optionally having a substituent, the rest representing a hydrogen atom or a hydroxy group.

In formula (2), M₁ is preferably manganese or ruthenium, and more preferably manganese.

In formulas (1) and (2), X represents OR¹, SR¹, NR²R³R⁴ or PX¹X²X³, and Y represents CO, OR¹, SR¹, NR²R³R⁴ or PX¹X²X³. X and Y may be identical or different. Here, R¹ represents a hydrocarbon group optionally having a substituent. One, two or three of R², R³ and R⁴ are identical or different and represent a hydrocarbon group optionally having a substituent, the rest representing a hydrogen atom.

One, two or three of X¹, X² and X³ are identical or different and represent a hydrocarbon group optionally having a substituent or a hydrocarbon oxy group optionally having a substituent, the rest representing a hydrogen atom or a hydroxy group.

The hydrocarbon groups optionally having a substituent represented by R¹, R², R³, R⁴, X¹, X² and X³ are identical or different, and are preferably any one of an alkyl group, an alkenyl group, a cycloalkyl group, a cycloalkenyl group and an aromatic hydrocarbon group, each of which optionally has one to three substituents selected from the group consisting of a primary, secondary or tertiary amino group, a hydroxy group, an alkoxy group, an aryloxy group, a halogen atom, a nitro group, a cyano group, a formyl group, an alkanoyl group and an arylcarbonyl group.

The alkyl group can be a straight or branched chain alkyl group having 1 to 20 carbon atoms, is preferably a straight or branched chain alkyl group having 1 to 12 carbon atoms, and is more preferably a straight or branched chain alkyl group having 1 to 6 carbon atoms. Specific examples include a methyl group, an ethyl group, a n-propyl group, an isopropyl group, a n-butyl group, an isobutyl group, a sec-butyl group, a tert-butyl group, a n-pentyl group and a n-hexyl group.

The alkenyl group can be a straight or branched chain alkenyl group having 2 to 20 carbon atoms, is preferably a straight or branched chain alkenyl group having 2 to 12 carbon atoms, and is more preferably a straight or branched chain alkenyl group having 2 to 6 carbon atoms. Specific examples include a vinyl group, a 2-propenyl group, a 1-propenyl group and a 1-butenyl group.

The cycloalkyl group can be a C₃-C₈ cycloalkyl group, and specific examples include a cyclopropyl group, a cyclobutyl group, a cyclopentyl group and a cyclohexyl group. The cycloalkenyl group can be a C₃-C₈ cycloalkenyl group, and specific examples include a cyclobutenyl group, a cyclopentenyl group and a cyclohexenyl group. The aromatic hydrocarbon group can be a C₆-C₁₄ aromatic hydrocarbon group, and specific examples include a phenyl group, a naphthyl group and a phenanthrenyl group.

The hydrocarbon oxy groups optionally having a substituent represented by X¹, X² and X³ are identical or different, and can be any one of an alkoxy group, an alkenyloxy group, a cycloalkyloxy group, a cycloalkenyloxy group and an aromatic hydrocarbon oxy group, each of which optionally has one to three substituents selected from the group consisting of a primary, secondary or tertiary amino group, a hydroxy group, an alkoxy group, an aryloxy group, a halogen atom, a nitro group, a cyano group, a formyl group, an alkanoyl group, and an arylcarbonyl group.

The alkoxy group can be a straight or branched chain alkoxy group having 1 to 20 carbon atoms, is preferably a straight or branched chain alkoxy group having 1 to 12 carbon atoms, and is more preferably a straight or branched chain alkoxy group having 1 to 6 carbon atoms. Specific examples include a methoxy group, an ethoxy group, a n-propyloxy group, an isopropyloxy group, a n-butyloxy group, an isobutyloxy group, a sec-butyloxy group, a tert-butyloxy group, a n-pentyloxy group, and a n-hexyloxy group.

The alkenyloxy group can be a straight or branched chain alkenyloxy group having 2 to 20 carbon atoms, is preferably a straight or branched chain alkenyloxy group having 2 to 12 carbon atoms, and is more preferably a straight or branched chain alkenyloxy group having 2 to 6 carbon atoms. Specific examples include a vinyloxy group, a 2-propenyloxy group, a 1-propenyloxy group, a 1-butenyloxy group, and the like.

The cycloalkyloxy group can be a C₃-C₈ cycloalkyloxy group, and specific examples include a cyclopropyloxy group, a cyclobutyloxy group, a cyclopentyloxy group and a cyclohexyloxy group. The cycloalkenyloxy group can be a C₃-C₈ cycloalkenyloxy group, and specific examples include a cyclobutenyloxy group, a cyclopentenyloxy group, a cylohexenyloxy group, and the like.

The aryloxy group can be a C₆-C₁₄ aryloxy group, and specific examples include a phenyloxy group, a naphthyloxy group, a phenanthrenyloxy group, and the like.

As the group which can be substituted for such a hydrocarbon group or hydrocarbon oxy group, one to three groups selected from the group consisting of an amino group, a C₁₋₆ alkylamino group, a di(C₁₋₆ alkyl)amino group, a di(hydroxy C₁₋₆ alkyl)amino group, a hydroxy C₁₋₆ alkylamio group, a hydroxy group, a C₁₋₆ alkoxy group, a C₁₋₁₄ aryloxy group, a halogen atom, a nitro group, a cyano group, a formyl group, a C₁₋₆ alkanoyl group and a C₆₋₁₄ arylcarbonyl group are more preferred. Besides, one to three groups selected from the group consisting of an amino group, a C₁₋₆ alkylamino group, a di(C₁₋₆ alkyl)amino group, a hydroxy C₁₋₆ alkylamino group, a di(hydroxy C₁₋₆ alkyl)amino group, a hydroxy group, a C₁₋₆ alkoxy group, a C₁₋₁₄ aryloxy group, and a halogen atom are further preferred.

One, two or three of R², R³ and R⁴ represent any of the above-described hydrocarbon groups, and the rest represents a hydrogen atom. Besides, one, two or three of X¹, X² and X³ represent any of the above-described hydrocarbon groups or hydrocarbon oxy groups, and the rest represents a hydrogen atom or a hydroxy group.

More preferable X is OR¹ or NR¹R²R³. Further preferable X is —OC₂₋ₛ alkyl NHC₂₋₈ alkyl OH, —OC₂₋₈ alkyl N(C₂₋₈ alkyl OH)₂, —NH(C₂₋₃ alkyl OH) or —N(C₂₋₈ alkyl OH)₂. Further preferable X is —OC₂₋₆ alkyl NHC₂₋₆ alkyl OH, —OC₂₋₆ alkyl N(C₂₋₆ alkyl OH)₂, —NH(C₂₋₆ alkyl OH), or —N(C₂₋₆ alkyl OH)₂. Still further preferable X is —OC₂H₄NHC₂H₄OH, —C₂H₄N(C₂H₄OH)₂, —NH(C₂H₄OH) or —N(C₂H₄OH)₂. Besides, more preferable Y is CO, OR¹ or NR¹R²R³, and further preferable Y is CO₂.

As the nitrogen atom-containing heterocycles including ring A and ring B, a heterocycle having a 2,2′-bipyridine structure optionally having a substituent is preferred. As a group which can be substituted in the heterocycle, one to four groups selected from the group consisting of an alkyl group, an alkoxy group, an aryloxy group, a halogen atom and an alkanoyl group are preferred, and one to four groups selected from the group consisting of a C₁₋₆ alkyl group, a C₁₋₆ alkoxy group, a C₆₋₁₄ aryloxy group, a halogen atom and a C₁₋₆ alkanoyl group are more preferred.

As the heterocycle having the 2,2′-bipyridine structure, for example, a heterocycle represented by the following formula (3) or (4) is preferred:

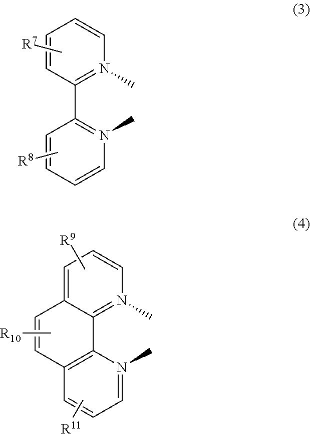

In the formulas, R⁷, R⁸, R⁹, R¹⁰ and R¹¹ are identical or different, and represent a hydrogen atom, an alkyl group, an alkoxy group, an aryloxy group, a halogen atom or an alkanoyl group.

Among these, the heterocycle of formula (3) is more preferred. More specifically, 2,2′-pyridine, 4,4′-dimethyl-2,2′-bipyridine, 4,4′-dibromo-2,2′-bipyridine and 4,4′-dimethoxy-2,2′-bipyridine are preferred.

Among metal complexes represented by the aforementioned formula (2), a metal complex represented by the following formula (2a) is novel, and is more preferred:

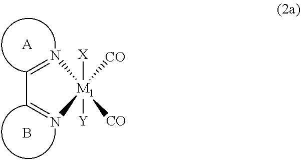

In the formula, M₁ represents manganese, ruthenium or iron; X represents O(CH₂)ₙNR⁵R⁶, NR⁵R⁶ or PX¹X²X³; Y represents CO, O(CH₂)ₙNR⁵R⁶, NR⁵R⁶ or PX¹X²X³; ring A and ring B are identical or different and represent a nitrogen atom-containing heterocycle optionally having a substituent; one, two or three of X¹, X² and X³ are identical or different and represent a hydrocarbon group optionally having a substituent or a hydrocarbon oxy group optionally having a substituent, the rest representing a hydrogen atom or a hydroxy group; R⁵ and R⁶ are identical or different and represent an alkyl group, a hydroxyalkyl group or a hydrogen atom; and n represents a number of 2 to 8.

As M¹, manganese or ruthenium is more preferred, and manganese is further preferred.

As the nitrogen atom-containing heterocycles including ring A and ring B, a heterocycle having a 2,2′-bipyridine structure optionally having a substituent is preferred, a heterocycle of the aforementioned formula (3) or (4) is more preferred, a heterocycle of formula (3) is further preferred, and 2,2′-bipyridine, 4,4′-dimethyl-2,2′-bipyridine, and 4,4′-dibromo-2,2′-bipyridine are particularly preferred.

R⁵ and R⁶ in O(CH₂)ₙNR⁵R⁶ and NR⁵R⁶ are identical or different, and represent an alkyl group, a hydroxyalkyl group or a hydrogen atom. More specifically, R⁵ and R⁶ can be a C₁₋₆ alkyl group, a hydroxy C₁₋₆ alkyl group or a hydrogen atom, and are preferably a C₁₋₄ alkyl group, a hydroxy C₁₋₆ alkyl group or a hydrogen atom.

As the hydrocarbon groups optionally having a substituent represented by X¹, X² and X³, any one of an alkyl group, an alkenyl group, a cycloalkyl group, a cycloalkenyl group and an aromatic hydrocarbon group, each of which optionally has one to three substituents selected from the group consisting of a primary, secondary or tertiary amino group, a hydroxy group, an alkoxy group, an aryloxy group, a halogen atom, a nitro group, a cyano group, a formyl group, an alkanoyl group and an arylcarbonyl group, is preferred.

The hydrocarbon oxy groups optionally having a substituent represented by X¹, X² and X³ are identical or different, and can be any one of an alkoxy group, an alkenyloxy group, a cycloalkyloxy group, a cycloalkenyloxy group and an aryloxy group, each of which optionally has one to three substituents selected from the group consisting of a primary, secondary or tertiary amino group, a hydroxy group, an alkoxy group, an aryloxy group, a halogen atom, a nitro group, a cyano group, a formyl group, an alkanoyl group and an arylcarbonyl group.

More preferable X is O(CH₂)ₙNR⁵R⁶ or NR⁵R⁶.

Further preferable X is —OC₂₋₈ alkyl NHC₂₋₈ alkyl OH, —OC₂₋₈ alkyl N(C₂₋₈ alkyl OH)₂, —NH(C₂₋₈ alkyl OH) or —N(C₂₋₈ alkyl OH)₂. Further preferable X is —OC₂₋₆ alkyl NHC₁₋₆ alkyl OH, —OC₂₋₆ alkyl N(C₂₋₆ alkyl OH)₂, —NH(C₂₋₆ alkyl OH) or —N(C₂₋₆ alkyl OH)₂. Further preferable X is —OC₂H₄NHC₂H₄OH, —OC₂H₄N(C₂H₄OH)₂, —NH(C₂H₄OH) or —N(C₂H₄OH)₂. Besides, more preferable Y is CO, O(CH₂)ₙNR⁵R⁶ or NR⁵R⁶, and further preferable Y is CO.

The metal complex represented by formula (1) or (2) can be produced in accordance with, for example, the following reaction formulas:

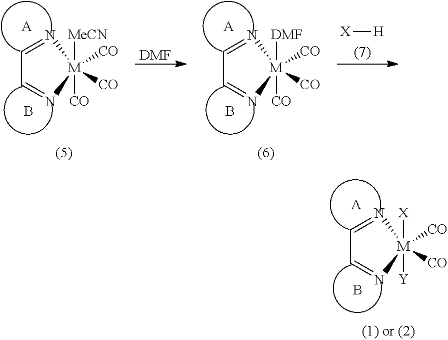

In the formulas, M represents rhenium, manganese, ruthenium or iron, and A, B, X and Y are the same as defined above.

Specifically, an acetonitrile (MeCN)-coordinated metal complex of formula (5) is converted into a solvent-coordinated complex (6) through a reaction with a solvent having comparatively low coordination ability such as dimethylformamide, and the resultant complex is reacted with X-H and/or Y-H (7) in a basic condition, and thus, the metal complex of formula (1) or (2) can be produced. The conversion from the acetonitrile-coordinated complex (5) to the solvent-coordinated complex may be performed by dissolving the complex of formula (5) in the above-described solvent, and allowing the resultant to stand still overnight in a dark place under Ar atmosphere. Next, for producing the complex of formula (1) or (2), the complex of formula (6) is added to X-H (7), and the resultant is allowed to stand still for several hours in a dark place under Ar atmosphere.

A method for producing CO from CO₂ by electrochemical reduction of the present invention is characterized by including the following steps (a) and (b):
(a) a step of reacting carbon dioxide with a metal complex represented by formula (1) described above; and
(b) a step of applying a voltage to a reaction product of the carbon dioxide and the metal complex represented by formula (1).

Reactions of the steps (a) and (b) are regarded to proceed in accordance with the following reaction formulas:

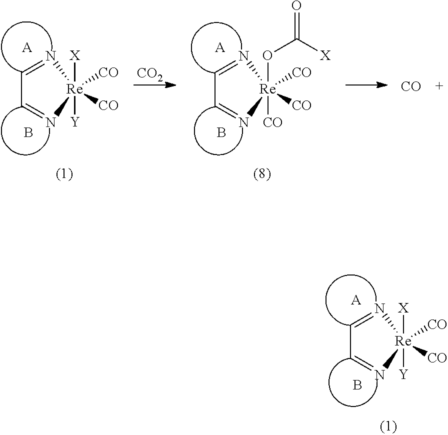

In the formulas, A, B, X and Y are the same as defined above.

Specifically, through the reaction between the metal complex of formula (1) and CO₂, a CO₂ adduct represented by formula (8) is generated, and when a voltage is applied to this adduct, CO is released. It is noted that the generation of the CO₂ adduct of formula (8) can be confirmed based on an IR spectrum, an MS spectrum and an NMR spectrum.

The reaction may be performed in an electrolyte solution, namely, a polar solvent, and from the viewpoint that an oxygen atom produced as a by-product simultaneously with CO released from the CO₂ adduct of formula (8) is changed into water through protonation, a protic polar solvent is preferably used. Examples of the protic polar solvent include water, an alcohol-based solvent, an amine-based solvent, a thiol-based solvent and an amino alcohol-based solvent. Among these, a solvent corresponding to X and/or Y of formula (1) is particularly preferably used.

The amount of the metal complex of formula (1) to be used is preferably 0.01 mM to 100 mM in the electrolyte solution, and more preferably 0.05 mM to 10 mM.

The CO₂ to be introduced is not necessarily 100% CO₂, and the CO generation reaction proceeds even if a gas containing 0.03% to 100% of CO₂ is used. The concentration of 0.03% of CO₂ gas corresponds to the CO₂ concentration in the ambient air. Besides, CO₂ of a waste gas containing about 10% of CO₂ from a thermal power station or the like can be directly used without concentration.

Besides, the CO₂ can be easily introduced by introducing a CO₂-containing gas into the electrolyte solution, for example, by bubbling a CO₂-containing gas through the electrolyte solution.

Next, for setting an application voltage, it is significant to grasp an application voltage level by precedently performing cyclic voltammetry (CV) measurement. The cyclic voltammetry (CV) measurement is a method in which an electrode potential is linearly swept to measure a response current. In the present invention, the cyclic voltammetry measurement is performed (a) in the absence (blank) or in the presence of the metal complex of the present invention in the electrolyte by introducing (b) Ar gas and (c) a CO₂-containing gas. When a current-potential curve is obtained in the condition (c), an application voltage (a reduction potential) can be obtained on the basis of a rising potential of the response current. Incidentally, the voltage may be applied while performing the reaction within an electrochemical cell including a working electrode and a counter electrode. The voltage is preferably 1.0 V to 2.5 V vs. Ag/AgNO₃.

Specifically, the steps (a) and (b) are performed within an electrochemical cell including a working electrode and a counter electrode, and the following steps (a1) and (b1) are preferably performed:
(a1) a step of introducing carbon dioxide into a solution containing the metal complex held in the electrochemical cell; and
(b1) a step of applying a negative voltage and a positive voltage respectively to the working electrode and the counter electrode of the electrochemical cell.

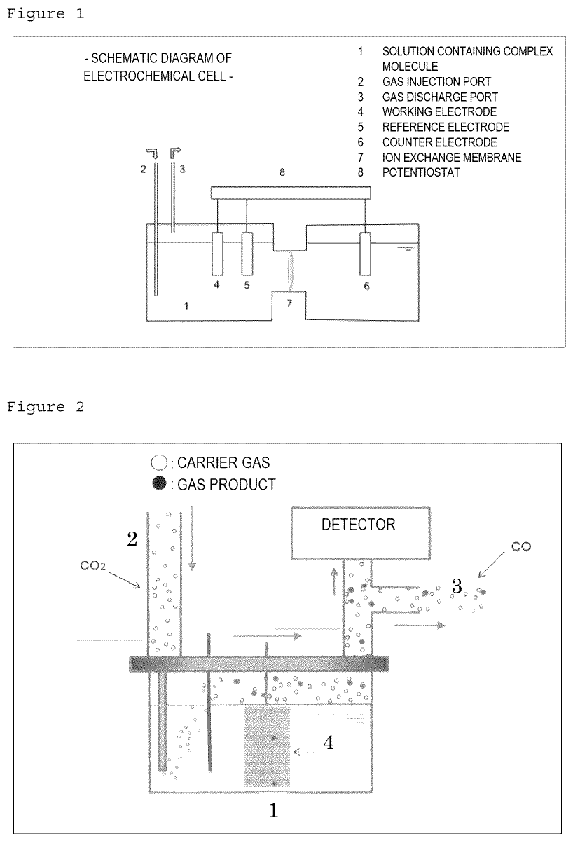

More specifically, it is preferable to use a system, for example, as illustrated in FIG. 1, for producing carbon monoxide from carbon dioxide through electrochemical reduction, the system including an electrochemical cell part equipped with a solution (1) containing a metal complex, a working electrode (4) and a counter electrode (6); an injection part (an injection port) (2) through which carbon dioxide is injected into the solution containing the metal complex held in the electrochemical cell part (1); a potentiostat (8) including a voltage source capable of applying a positive or negative voltage between the working electrode (4) and the counter electrode (6) of the electrochemical cell part; and a discharge part (a discharge port) (3) through which carbon monoxide generated within the solution containing the metal complex is discharged, so that the carbon monoxide can be generated by applying a positive or negative voltage to a reaction product of the metal complex generated by the solution containing the metal complex and the carbon dioxide.

FIG. 2 illustrates an apparatus more practical than that illustrated in FIG. 1. The description will now be given on the basis of FIGS. 1 and 2.

In FIGS. 1 and 2, a reference sign (2) denotes a CO₂ injection part (injection port), through which CO₂ contained in white dots illustrated in FIG. 2 is introduced into a solution containing a metal complex. In FIGS. 1 and 2, a reference sign (1) denotes an electrochemical cell part, and the cell part includes a solution including a working electrode (4), and a reference electrode (5) and a counter electrode (6). Addition of CO₂ and a reduction reaction to CO are carried out through the metal complex of the working electrode. Glassy carbon or the like is used as the working electrode. Platinum or the like is used as the counter electrode.

In FIG. 1, a reference sign (8) denotes a potentiostat for applying a positive or negative voltage to the working electrode and the counter electrode of the electrochemical cell part.

In FIG. 2, a reference sign (3) denotes a gas discharge part for discharging CO (illustrated as gray dots) generated within the solution containing the metal complex. This CO discharge part can be provided with any of various CO sensors (of semiconductor type, thermal conductivity type and the like) or a detection part (a detector) detecting generation of carbon monoxide by gas chromatography (Micro-GC).

The system of the present invention can continuously produce CO from a CO₂-containing gas having a concentration of about 10% as illustrated in FIGS. 1 and 2, and therefore, can be installed in facilities where CO₂ is generated through combustion of organic substances, such as a thermal power station, a cement manufacturing facility and a glass manufacturing facility. Besides, it can be installed in a facility where Fe₂O₃ is reduced with CO, such as a blast furnace of an ironworks. In this case, the CO obtained by the method or the system of the present invention can be used as a reducing agent, so as to reproduce CO by using generated CO₂ as a raw material. Besides, if CO obtained by the method or the system of the present invention is used as a raw material, a wide range of hydrocarbon-based compounds can be produced.

A method for producing formic acid by electrochemically reducing CO₂ of the present invention is characterized by including the following steps (a) and (b):
(a) a step of reacting carbon dioxide with a metal complex represented by formula (2) described above; and
(b) a step of applying a voltage to a reaction product of the carbon dioxide and the metal complex represented by formula (2).

Reactions of the steps (a) and (b) are regarded to proceed in accordance with the following reaction formulas:

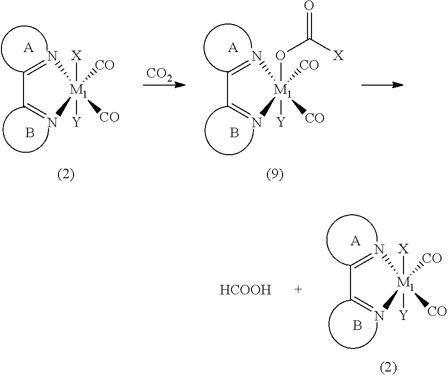

In the formulas, A, B, M₁, X and Y are the same as defined above.

Specifically, through the reaction between the metal complex of formula (2) and CO₂, a CO₂ adduct represented by formula (9) is generated, and when a voltage is applied to this adduct, formic acid is released. It is noted that the generation of the CO₂ adduct of formula (9) can be confirmed based on an IR spectrum and an MS spectrum.

The reaction may be performed in an electrolyte solution, namely, a polar solvent, and from the viewpoint that formic acid is released from the CO₂ adduct of formula (9), a protic polar solvent is preferably used. Examples of the protic polar solvent include water, an alcohol-based solvent, an amine-based solvent, a thiol-based solvent and an amino alcohol-based solvent. Among these, a solvent corresponding to X and/or Y of formula (2) is particularly preferably used.

The amount of the metal complex of formula (2) to be used is preferably 0.01 mM to 100 mM in the electrolyte solution, and more preferably 0.05 mM to 10 mM.

The CO₂ to be introduced is not necessarily 100% CO₂, and the CO generation reaction proceeds even if a gas containing 0.03% to 100% of CO₂ is used. The concentration of 0.03% of CO₂ gas corresponds to the CO₂ concentration in the ambient air. Besides, CO₂ of a waste gas containing about 10% of CO₂ from a thermal power station or the like can be directly used without concentration.

Besides, the CO₂ can be easily introduced by introducing a CO₂-containing gas into the electrolyte solution, for example, by bubbling a CO₂-containing gas through the electrolyte solution.

Next, for setting an application voltage, it is significant to grasp an application voltage level by precedently performing the cyclic voltammetry (CV) measurement. The cyclic voltammetry (CV) measurement is a method in which an electrode potential is linearly swept to measure a response current. In the present invention, the cyclic voltammetry measurement is performed (a) in the absence (blank) or in the presence of the metal complex of the present invention in the electrolyte by introducing (b) Ar gas and (c) a CO₂-containing gas. When a current-potential curve is obtained in the condition (c), an application voltage (a reduction potential) can be obtained on the basis of a rising potential of the response current. Incidentally, the voltage may be applied while performing the reaction within an electrochemical cell including a working electrode and a counter electrode. The voltage is preferably 1.0 V to 2.5 V vs. Ag/AgNO₃.

According to the method of the present invention, formic acid can be continuously produced from a CO₂-containing gas having a concentration of about 0.03%, and therefore, the method can be employed in facilities where CO₂ is generated through combustion of organic substances, such as a thermal power station, a cement manufacturing facility and a glass manufacturing facility.

### EXAMPLES

Next, the present invention will be described in more detail with reference to examples.

### Synthesis Example 1

### Re(CO)₅Br

Four (4) mL of bromine was added in a dropwise manner to dichloromethane (8 mL) containing Re₂(CO)₁₀ (4.71 g, 7.21 mmol), and the resultant was stirred at room temperature for 10 minutes. A white solid thus separated was filtered off.

Yield: 5.47 g (13.4 mmol), Yield: 93.1%

FT-IR in CH₂Cl₂ ν(CO)/cm⁻¹: 2154, 2046, 1988.

### Synthesis Example 2

Re(bpy)(CO)₃Br (sometimes abbreviated as Re—Br)

A toluene solution (60 mL) containing Re(CO)₅Br (3.00 g, 7.38 mmol) and 2,2′-bipyridine (bpy) (1.27 g, 8.14 mmol) was heated to reflux overnight. A yellow solid thus separated was filtered off and dried under reduced pressure. The resultant was purified by recrystallization using acetonitrile/diethyl ether/hexane.

Yield: 3.63 g (7.18 mmol), Yield: 97.3%

ESI-MS in CH₂Cl₂ m/z=468 [M—PF₆⁻]⁺

FT-IR in CH₂Cl₂ ν(CO)/cm⁻¹: 2024, 1923, 1901

¹H NMR in CDCl₃: δ (ppm)=9.09 (d, J=7.0 Hz, 2H, bpy-6,6′), 8.21 (d, J=7.0 Hz, 2H, bpy-3,3′), 8.07 (dd, J=7.0, 7.0 Hz, 2H, bpy-4,4′), 7.55 (dd, J=7.0, 7.0 Hz, 2H, bpy-5,5′)

Elemental analysis: Calcd. (%) for C₁₃H₁₀N₂O₃BrRe: C, 30.84; H, 1.59; N, 5.53.

Found: C, 30.86; H, 1.46; N, 5.61.

### Synthesis Example 3

### Re(dmb)(CO)₃Br

A toluene solution (60 mL) containing Re(CO)₅Br (1.10 g, 2.71 mmol) and 4-4′-dimethyl-2,2′-bipyridine (dmb) (0.55 g, 3.00 mmol) was heated to reflux overnight. A yellow solid thus separated was filtered off and dried under reduced pressure.

Yield: 1.40 g (2.62 mmol), Yield: 96.7%

FT-IR in CH₂Cl₂ ν (CO)/cm⁻¹: 2022, 1920, 1898

### Synthesis Example 4

Re{(MeO)₂bpy}(CO)₃Br

A toluene solution (60 mL) containing Re(CO)₅Br (499 mg, 1.23 mmol) and 4,4′-dimethoxy-2,2′-bipyridine (1MeO)₂bpy (321 mg, 1.483 mmol) was heated to reflux overnight. A yellow solid thus separated was filtered off and dried under reduced pressure.

Yield: 652 mg (1.15 mmol), Yield: 93.7%

FT-IR in CH₂Cl₂ ν(CO)/cm⁻¹: 2022, 1918, 1895

### Synthesis Example 5

Re(Br₂bpy)(CO)₃Br

A toluene solution (60 mL) containing Re(CO)₅Br (503 mg, 1.24 mmol) and 4-4′-dibromo-2,2′-bipyridine (Br₂bpy) (464 mg, 1.48 mmol) was heated to reflux overnight. A yellow solid thus separated was filtered off and dried under reduced pressure.

Yield: 803 mg (1.21 mmol), Yield: 97.7%

FT-IR in CH₂Cl₂ ν(CO)/cm⁻¹: 2026, 1928, 1905

### Synthesis Example 6

[Re(bpy)(CO)₃(MeCN)](PF₆) (Sometimes Abbreviated as Re-MeCN)

Acetonitrile (60 mL) containing Re(bpy)(CO)₃Br (596 mg, 1.18 mmol) and AgPF₆ (327 mg, 1.29 mmol) was heated to reflux overnight. AgBr thus separated was removed over a Celite layer, and the solvent was distilled off under reduced pressure. To the resultant, saturated NH₄PF₆ in acetonitrile/water (1:1 v/v) was added, and the acetonitrile was slowly distilled off under reduced pressure to obtain a pale yellow solid. This solid was recrystallized from acetonitrile/diethyl ether/hexane, and a yellow solid thus obtained was dried under reduced pressure.

Yield: 363 mg, (5.92×10⁻¹ mmol), Yield: 50.3%

ESI-MS in MeCN m/z=468 [M-PF₆⁻]⁺

FT-IR in MeCN ν(CO)/cm⁻¹: 2041, 1938

¹H-NMR in CD₃CN (298 MHz): δ (ppm)=9.02 (dd, J=5.6, 1.5 Hz, 2H, bpy-6,6′), 8.47 (dd, J=8.2, 1.1 Hz, 2H, bpy-3,3′), 8.28 (ddd, J=8.2, 8.2, 1.5 Hz, 2H, bpy-4,4′), 7.71 (ddd, J=8.2, 5.6, 1.1 Hz, 2H, bpy-5,5′), 2.03 (s, 3H, CH₃CN)

Elemental analysis: Calcd. (%) for C₁₅H₁₃N₃O₃RePF₆: C, 29.40; H, 1.81; N, 6.86.

Found: C, 29.35; H, 1.65; N, 6.91.

### Synthesis Example 7

[Re(dmb)(CO)₃(MeCN)](PF₆) (Sometimes Abbreviated as (Re(Me)MeCN)

An acetonitrile solution (60 mL) containing Re(dmb)(CO)₃Br (500 mg, 9.34×10⁻¹ mmol) and AgPF₆ (303 mg, 1.19 mmol) was heated to reflux overnight. AgBr thus separated was removed over a Celite layer, and the solvent was distilled off under reduced pressure. To the resultant, saturated NH₄PF₆ in acetonitrile/water (1:1 v/v) was added, and the acetonitrile was slowly distilled off under reduced pressure to obtain a pale yellow solid. This solid was recrystallized from acetonitrile/diethyl ether/hexane, and a pale yellow solid thus obtained was dried under reduced pressure.

Yield: 478.6 mg, (7.47×10⁻¹ mmol), Yield: 79.9%

ESI-MS in MeCN m/z=496 [M-PF₆⁻]+

FT-IR in MeCN ν(CO)/cm⁻¹: 2039, 1935

¹H-NMR in CD₃CN (298 MHz): δ (ppm)=8.82 (d, J=5.5 Hz, 2H, bpy-6,6′), 8.32 (s, 2H, bpy-3,3′), 7.52 (d, J=5.5 Hz, 2H, bpy-5,5′), 2.58 (s, 6H, bpy-CH₃), 2.04 (s, 3H, CH₃—CN)

Elemental analysis: Calcd. (%) for C₁₇H₁₅N₃O₃RePF₆: C, 31.88; H, 2.36; N, 6.56.

Found: C, 31.85; H, 2.19; N, 6.59.

### Synthesis Example 8

[Re{(MeO)₂bpy}(CO)₃(MeCN)](PF₆) (Sometimes Abbreviated as Re(MeO)MeCN)

An acetonitrile solution (60 mL) containing Re{(MeO)₂bpy}(CO)₃Br (601 mg, 1.06 mmol) and AgPF₆ (290 mg, 1.15 mmol) was heated to reflux overnight. AgBr thus separated was removed over a Celite layer, and the solvent was distilled off under reduced pressure. To the resultant, saturated NH₄PF₆ in acetonitrile/water (1:1 v/v) was added, and the acetonitrile was slowly distilled off under reduced pressure to obtain a pale yellow solid. This solid was recrystallized from acetonitrile/diethyl ether/hexane, and a pale yellow solid thus obtained was dried under reduced pressure.

Yield: 443 mg (6.59×10⁻¹ mmol), Yield: 62.1%

ESI-MS in MeCN m/z=528 [M-PF₆⁻]+

FT-IR in MeCN ν(CO)/cm⁻¹: 2038, 1932

¹H-NMR in CD₃CN (298 MHz): δ (ppm)=8.76 (d, J=6.6 Hz, 2H, bpy-6,6′), 7.92 (d, 2.7 Hz, 2H, bpy-3,3′), 7.19 (dd, J=2.7, 6.6 Hz, 2H, bpy-5,5′), 4.03 (s, 6H, CH₃O), 2.05 (s, 3H, CH₃—CN)

Elemental analysis: Calcd. (%) for C₁₇H₁₅N₃O₅RePF₆: C, 30.36; H, 2.25; N, 6.25.

Found: C, 30.85; H, 2.24; N, 6.43.

### Synthesis Example 9

[Re(Br₂bpy)(CO)₃(MeCN)](PF₆) (Sometimes Abbreviated as Re(Br)MeCN)

An acetonitrile solution (60 mL) containing Re(Br₂bpy)(CO)₃Br (600 mg, 9.04×10⁻¹ mmol) and AgPF₆ (242.4 mg, 9.59×10⁻¹ mmol) was heated to reflux overnight. AgBr thus separated was removed over a Celite layer, and the solvent was distilled off under reduced pressure. To the resultant, saturated NH₄PF₆ in acetonitrile/water (1:1 v/v) was added, and the acetonitrile was slowly distilled off under reduced pressure to obtain a pale yellow solid. This solid was recrystallized from acetonitrile/diethyl ether/hexane, and a reddish brown solid thus obtained was dried under reduced pressure.

Yield: 435 mg (5.65×10⁻¹ mmol), Yield: 62.5%

ESI-MS in MeCN m/z=626 [M-PF₆⁻]+

FT-IR in MeCN η(CO)/cm⁻¹: 2042, 1941

¹H-NMR in CD₃CN (298 MHz): δ (ppm)=8.81 (d, J=6.0 Hz, 2H, bpy-6,6′), 8.72 (d, 2.0 Hz, 2H, bpy-3,3′), 7.92 (dd, J=2.0, 6.0 Hz, 2H, bpy-5,5′), 2.06 (s, 3H, CH₃—CN)

Elemental analysis: Calcd. (%) for C₁₅H₉N₃O₃Br₂RePF₆: C, 23.39; H, 1.18; N, 5.46.

Found: C, 23.56; H, 1.10; N, 5.62.

### Synthesis Example 10

### Re(bpy)(CO)₃(OCOH) (Sometimes Abbreviated as Re—OCOH)

An ethanol/water mixed solution (1:1 v/v, 50 mL) containing Re(bpy)(CO)₃Br (301 mg, 5.95×10⁻¹ mmol) and an excessive amount of sodium formate (4.05 g, 59.6 mmol) was heated to reflux overnight. The ethanol was slowly distilled off under reduced pressure. Dichloromethane was added thereto, and the resultant was extracted with water three times. After distilling off the solvent of the thus obtained organic layer under reduced pressure, the resultant was recrystallized from acetone/diethyl ether/hexane, and a yellow solid thus obtained was dried under reduced pressure.

Yield: 70.4 mg (1.49×10⁻¹ mmol), Yield: 25.1%

ESI-MS in MeCN m/z=626 [M-PF₆⁻]+

FT-IR in CH₂Cl₂ ν(CO)/cm⁻¹: 2022, 1918, 1896

¹H-NMR in CD₃CN (298 MHz): δ (ppm)=9.02 (dd, 2H, J=5.6, 1.6 Hz, bpy-6,6′), 8.40 (dd, 2H, J=8.3, 1.1 Hz, bpy-3,3′), 8.20 (ddd, 2H, J=8.3, 8.3, 1.6 Hz, bpy-4,4′), 7.61 (ddd, 2H, J=8.3, 5.6, 1.1 Hz, bpy-5,5′), 7.81 (s, 1H, HCOO)

Elemental analysis: Calcd. (%) for C₁₄H₉N₂O₅Re: C, 35.67; H, 1.92; N, 5.94.

Found: C, 35.63; H, 1.82; N, 6.01.

### Synthesis Example 11

### Re(bpy)(CO)₃(OTf)

A tetrahydrofuran solution (60 mL) containing Re(bpy)(CO)₃Br (1.00 g, 1.97 mmol) and AgOTf (553 mg, 2.15 mmol) was heated to reflux overnight. AgBr thus separated was removed over a Celite layer, and the solvent was distilled off under reduced pressure. The thus separated solid was recrystallized from dichloromethane/dimethyl ether/hexane, and a yellowish brown solid thus obtained was dried under reduced pressure.

Yield: 902 mg (1.56 mmol), Yield: 79.0%

FT-IR ν_{co} [cm⁻¹] in CH₂Cl₂: 2036, 1935, 1915

### Synthesis Example 12

[Re{4,4′-(MeO)₂bpy}(CO)₃{P(OC₂H₅)₃}](PF₆)

A tetrahydrofuran solution containing Re[4,4′-(MeO)₂bpy(CO)₃MeCN] (501 mg, 7.44×10⁻¹ mmol) and P(OC₂H₅)₃ (ca. 1 mL, 6 mmol) was heated to reflux in a dark place overnight. While blocking light, the solvent and an unreacted portion of P(OC₂H₅)₃ were distilled off under reduced pressure by using an oil sealed rotary pump. The thus obtained solid was recrystallized from dichloromethane/diethyl ether, and the resultant was separated and purified by flash column chromatography (elution solution: dichloromethane:methanol=100:0 to 100:3 v/v). The third fraction thus obtained was further recrystallized from dichloromethane/dimethyl ethanol, and a pale yellow solid thus obtained was dried under reduced pressure. Yield:

413 mg (5.18×10⁻¹ mmol), Yield: 69.6%

ESI-MS in MeCN m/z=653 [M-PF₆⁻]+

FT-IR in CH₂Cl₂ ν(CO)/cm⁻¹: 2044, 1958, 1925

¹H-NMR in CD₃CN (298 MHz): δ (ppm)=8.59 (d, J=6.4 Hz, 2H, bpy-6,6′), 7.94 (d, J=2.6 Hz, 2H, bpy-3,3′), 7.09 (dd, J=2.6, 6.4 Hz, 2H, bpy-5,5′), 4.16 (s, 6H, CH₃O), 3.82 (quin, J=7.1, 7.1, 7.1, 7.1 Hz, 6H, OCH₂CH₃), 1.09 (t, J=7.1, 7.1 Hz, 9H, OCH₂CH₃)

Elemental analysis: Calcd. (%) for C₂₁H₂₇N₂O₈F₆P₂Re: C, 31.62; H, 3.41; N, 3.51.

Found: C, 31.67; H, 3.25; N, 3.57.

### Synthesis Example 13

### Re(bpy)(CO)₃(OH)

An acetone/water mixed solution (4:3 v/v, 70 mL) containing Re(bpy)(CO)₃(OTf) (303 mg, 5.21×10⁻¹ mmol) and potassium hydroxide (1.35 g, 24.1×10 mmol) was heated to reflux overnight. The acetone was slowly distilled off under reduced pressure, and a yellow solid thus separated was filtered off and dried under reduced pressure.

Yield: 120 mg (2.71×10⁻¹ mmol), Yield: 51.5%

### Synthesis Example 14

Re(bpy)(CO)₃(OCO₂H)

A CO₂ gas was allowed to pass through an acetone solution containing Re(bpy)(CO)₃(OH) (52.0 mg, 1.17×10⁻¹ mmol) for 20 minutes. A yellow solid thus separated was filtered off and dried under reduced pressure.

Yield: 51.5 mg (1.06×10⁻¹ mmol), Yield: 90.1%

FT-IR in KBr ν(CO)/cm⁻¹: 2022, 1895, 1616, 1602

### Synthesis Example 15

[Re(bpy)(CO)₃(DMF)](PF₆)

[Re(bpy)(CO)₃(MeCN)](PF₆) (56.3 mg, 92.0 μmol) was dissolved in DMF-d₇, and the resultant was allowed to stand still in a dark place under Ar atmosphere for 12 hours to completely replace a MeCN ligand with DMF.

¹H NMR in DMF-d₇ (500 MHz): δ (ppm)=9.27 (ddd, 2H, J=0.5, 1.0, 5.5 Hz, bpy-6,6′), 8.95 (d, 2H, J=8.0 Hz, bpy-3,3′), 8.54 (ddd, 2H, J=1.0, 8.0, 8.0 Hz, bpy-4,4′), 7.97 (ddd, 2H, J=1.0, 5.5, 8.0 Hz, bpy-5,5′)

¹³C NMR in DMF-d₇ (126 MHz): δ (ppm)=196.9, 193.2, 156.5, 154.9, 142.0, 128.9, 125.2

FT-IR in DMF ν(CO)/cm⁻¹: 2029, 1922, 1913

### Synthesis Example 16

Re(bpy)(CO)₃{O—CO—OCH₂CH₂N(CH₂CH₂OH)₂}

To a DMF solution (2 mL) containing [Re(bpy)(CO)₃(DMF)]⁺, triethanolamine (TEOA, 200 μL) was added. The resultant was allowed to stand still for 12 hours to partially replace a DMF ligand with TEOA, and thus, the resultant was changed to an equilibrium mixture of [Re(bpy)(CO)₃(DMF)]⁺ and Re(bpy)(CO)₃ (TEOA).

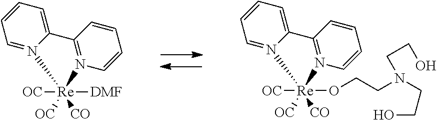

Through the resultant solution, CO₂ was allowed to pass for 30 minutes. At this point, Re(bpy)(CO)₃OCO₂H was precipitated and hence was filtered off, and the resultant filtrate was used as a sample solution for an NMR spectrum.

¹H NMR in DMF-d₇-TEOA (10:1 v/v)(500 MHz): δ (ppm)=9.19 (ddd, 2H, J=0.5, 1.0, 5.5 Hz, bpy-6,6′), 8.82 (d, 2H, J=8.0 Hz, bpy-3,3′), 8.42 (ddd, 2H, J=1.0, 8.0, 8.0 Hz, bpy-4,4′), 7.87 (ddd, 2H, J=1.0, 5.5, 8.0 Hz, bpy-5,5′)

¹³C NMR in DMF-d₇-TEOA (10:1 v/v)(126 MHz): δ (ppm)=198.4, 194.4, 158.4 (C═O), 156.0, 153.8, 140.9, 128.0, 124.4

FT-IR in DMF-TEOA (5:1 v/v) ν(CO)/cm⁻¹: 2020, 1915, 1892

ESI-MS in MeCN m/z=620 [M+H⁺—PF₆⁻]⁺, 642 [M+Na⁺—PF₆⁻]⁺

### Synthesis Example 17

### Mn(bpy)(CO)₃Br

A diethyl ether solution (400 mL) containing 2,2′-bipyridine (bpy) (0.57 g, 3.65 mmol) and Mn(CO)₃Br (1.0 g, 3.65 mmol) was heated to reflux for 3 hours. An orange powder thus separated was filtered off, washed with diethyl ether, and dried under reduced pressure.

Yield: 1.26 g (92.6%)

¹H NMR (400 MHz, aceton-d₆, ppm) δ=9.30 (d, 2H, J=4.8 Hz; 2H; H6,6′), 8.58 (d, 2H, J=8.2 Hz, H3,3′), 8.23 (td, 2H, J=5.9 Hz), 7.75 (t, J=5.9 Hz, 2H; H5,5′).

FT-IR (CH₂Cl₂): ν(CO)/cm⁻¹, 2028, 1938, 1922.

### Synthesis Example 18

[Mn (bpy)(CO)₃CH₃CN] PF₆

An acetonitrile solution (350 mL) containing AgPF₆ (0.69 g, 3.65 mmol) and Mn(bpy)(CO)₃Br (1.00 g, 2.71 mmol) was heated to 40° C. for 1 hour. The thus obtained mixture was filtered through Celite. The resultant filtrate was evaporated to dryness, and the thus obtained solid was washed with diethyl ether and dried under reduced pressure.

Yield: 1.23 g (96.0%)

¹H NMR (400 MHz, CD₃Cl₃, ppm) δ=9.04 (d, 2H, J=3.6 Hz; 2H; H6,6′), 8.41 (d, 2H, J=7.6 Hz, H3,3′), 8.22 (td, 2H, J=5.9 Hz, H4,4′), 7.66 (t, 2H, J=5.9 Hz, H5,5′), 2.10 (s, 3H, CH₃)

FT-IR (CH₃CN): ν(CO)/cm⁻¹, 2028, 1938, 1923.

Elemental Anal. Calcd (%) for C₁₃H₈BrMnN₂O₃: C, 37.44: H, 2.30; N, 8.73.

Found: C, 37.56: H, 2.21; N, 8.83.

### Synthesis Example 19

### Mn (MeObpy)(CO)₃Br

Mn(MeOpby)(CO)₃Br was obtained in the same manner as the synthesis of Mn(bpy)(CO)₃Br of Synthesis Example 18.

Yield: 96.3%

¹H NMR (400 MHz, aceton-d₆, ppm) δ=9.02 (d, 2H, J=6.4 Hz; H6,6′), 8.13 (d, 2H, J=2.0 Hz, H3,3′), 7.30 (dd, 2H, J=6.4, 2.0 Hz, H5,5′), 4.12 (s, 6H, OCH₃)

FT-IR (CH₂Cl₂): ν(CO)/cm⁻¹ 2026, 1930, 1918.

### Synthesis Example 20

[Mn (MeObpy)(CO)₃CH₃CN] PF₆

[Mn(MeObpy)(CO)₃CH₃CN]PF₆ was obtained in the same manner as the synthesis of [Mn(bpy)(CO)₃CH₃CN]PF₆ of Synthesis Example 18.

Yield: 75.1%

¹H NMR (400 MHz, CD₃Cl₃, ppm) δ=8.72 (d, 2H, J=6.4 Hz; 2H; H6,6′), 7.81 (d, 2H, J=2.6Ha, H3,3′), 7.82 (td, 2H, J=2.6, 6.4 Hz, H4,4′), 4.11 (s, 6H, OCH₃), 2.16 (s, 3H, NCCH₃)

FT-IR (CH₃CN): ν(CO)/cm⁻¹, 2047, 1953.

### Synthesis Example 21

### Mn(Brbpy)(CO)₃Br

Mn(Brbpy)(CO)₃Br was obtained in the same manner as the synthesis of Mn(bpy)(CO)₃Br of Synthesis Example 17.

Yield: 0.64 g (94.5%)

¹H NMR (400 MHz, aceton-d₆, ppm) δ=9.17 (d, 2H, J=6.0 Hz, 2H, H6,6′), 8.94 (d, 2H, J=1.8 Hz, H3,3′), 8.01 (dd, 2H, J=5.6, 1.8 Hz, H5,5′)

FT-IR (CH₂Cl₂): ν(CO)/cm⁻¹, 2030, 1938.

### Synthesis Example 22

[Mn(Brbpy)(CO)₃CH₃CN] PF₆

[Mn(Brbpy)(CO)₃CH₃CN]PF₆ was obtained in the same manner as the synthesis of [Mn(bpy)(CO)₃CH₃CN]PF₆ of Synthesis Example 18.

Yield: 1.23 g (96.6%)

¹H NMR (400 MHz, CDCl₃, ppm) δ=8.83 (d, 2H, J=5.8 Hz; 2H; H6,6′), 8.42 (d, 2H, J=2.2 Hz, H3,3′), 7.82 (td, 2H, J=2.2, 5.8 Hz, H4,4′), 2.16 (s, 3H, CH₃, H)

FT-IR (CH₃CN): ν(CO)/cm⁻¹, 2051, 1963.

Elemental Anal. Calcd (%) for C₁₅H₉Br₂MnN₃O₃: C, 28.20; H, 1.42; N, 6.58.

Found: C, 28.50; H, 1.28; N, 6.69.

### Synthesis Example 23 (CO₂ Addition Reaction to Metal Complex of Formula (1))

(1) Generation of Re—CO₂-TEOA in DMF-TEOA Mixed Solution

CO₂ was allowed to pass through a solution containing a rhenium complex to attempt to observe a rhenium complex to which CO₂ had been added.

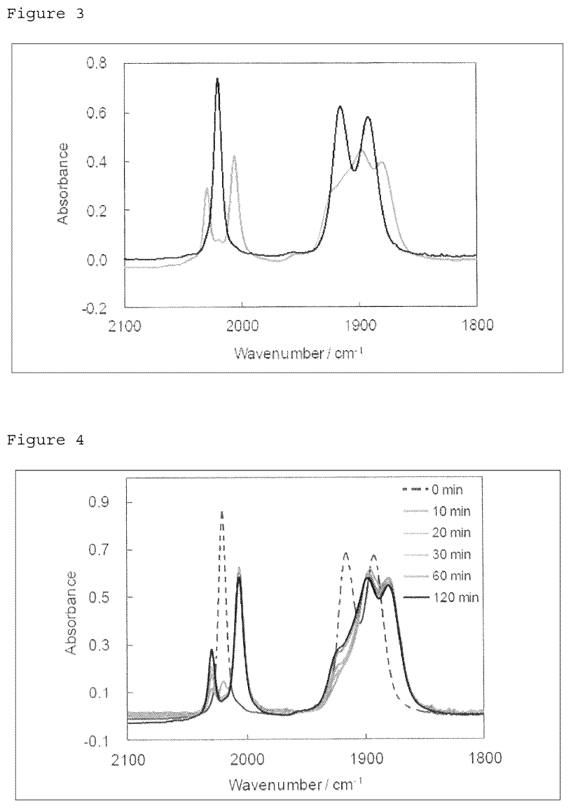

Re-MeCN was dissolved in DMF to a concentration of 5.30 mM, and the resultant was allowed to stand still in a dark place under Ar atmosphere. Thereafter, TEOA was added thereto, and the resultant was allowed to stand still again in a dark place under Ar atmosphere. Then, CO₂ was allowed to pass through the thus obtained DMF-TEOA mixed solution for 30 minutes. IR spectrum change of the resultant solution is illustrated in FIG. 3. Besides, change in color of the solution was observed. Furthermore, Ar was allowed to pass for 2 hours through the solution through which CO₂ had passed, so as to remove dissolved CO₂ from the solution. IR spectrum change thus caused is illustrated in FIG. 4.

When CO₂ was allowed to pass through this equilibrium mixture, all peaks precedently observed disappeared, and new peaks were observed at 2020 cm⁻¹, 1915 cm⁻¹ and 1892 cm⁻¹ (FIG. 3). It can be determined based on the shapes of these IR peaks that a newly produced complex retains a tricarbonyl structure. Besides, when CO₂ was allowed to pass through, the color of the solution was changed from reddish brown to yellow, which suggests that some sort of reaction was caused between Re-DMF or Re-TEOA and CO₂. Even if CO₂ was allowed to pass through a DMF solution containing Re-DMF, the IR spectrum was not changed. Accordingly, it is presumed that the reaction is caused between Re-TEOA and CO₂. Besides, the peak of the newly produced complex (Re—CO₂-TEOA) is positioned on a lower frequency side of the peak of Re-DMF but on a higher frequency side of the peak of Re-TEOA. This relationship in the wavelength reveals that the electron-donating property of a ligand of Re—CO₂-TEOA is stronger than that of a DMF ligand but weaker than that of a TEOA ligand.

When Ar was allowed to pass through, the peaks of Re—CO₂-TEOA were largely reduced, and mainly the peaks of Re-TEOA were recovered. After 2 hours, the peaks of Re—CO₂-TEOA completely disappeared (FIG. 4), and a concentration ratio between Re-DMF and Re-TEOA became substantially the same as that in the equilibrium state obtained before allowing CO₂ to pass therethrough. Accordingly, it was found that the generation reaction of Re-CO₂-TEOA is reversible and that the equilibrium depends on the CO₂ concentration in the solution.

(2) Determination of Structure of Re-CO₂-TEOA

An attempt was made to specify the structure of Re-CO₂-TEOA from the MS spectrum and the NMR spectrum thereof.

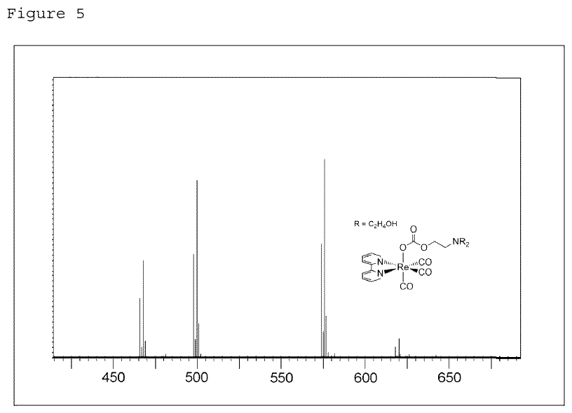

FIG. 5 illustrates an ESI-MS spectrum of a DMF-TEOA mixed solution (5:1 v/v) containing Re—CO₂-TEOA. Peaks were mainly observed at not only Re-MeCN (m/z=468), Re-DMF (m/z=500) and Re-TEOA (m/z=576) but also m/z=620.

The peak at m/z=620 corresponds to a monovalent complex (m/z=619.62) resulting from addition of CO₂ (exact mass=44.01) and TEOA (exact mass=149.19) to Re(bpy)(CO)₃ (exact mass=426.42).

It was concluded, on the basis of 1H-NMR and ¹³C-NMR, that Re(bpy)(CO)₃{O—CO—OCH₂CH₂N(CH₂CH₂OH)₂} represented by the following formula had been generated:

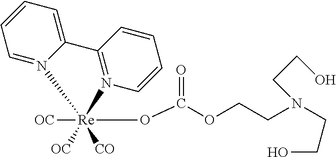

(3) Uptake of CO₂ from Air by Re-TEOA

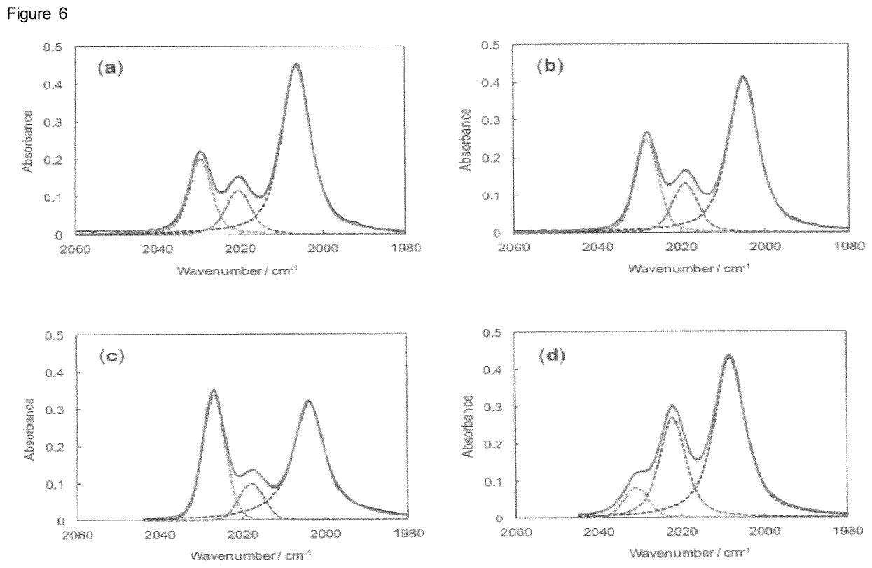

With general air allowed to pass through instead of 100% CO₂ gas, it was checked whether or not CO₂ in the ambient air was taken in by Re-TEOA. Besides, with an electron-withdrawing or electron-donating substituent introduced into the 4,4′-position of the bpy ligand, the relationship between the electron density of the central metal and CO₂ uptake ability was also checked. Re-MeCN, Re(Me)MeCN, Re(MeO)MeCN and Re(Br)MeCN respectively containing a bpy ligand in which hydrogen, a methyl group, a methoxy group or a bromo group was substituted in the 4,4′-position were synthesized. Each of these complexes was dissolved in DMF, the resultant was allowed to stand still in a dark place under Ar atmosphere overnight, and then, TEOA was added thereto, the resultant was allowed to stand still in a dark place under Ar atmosphere for 2 hours, and thus, a DMF-TEOA mixed solution (5:1 v/v) containing the complex in which DMF or TEOA was coordinated was prepared. Change in the IR spectrum caused by allowing the ambient air to pass through each of such solutions for 1 to 2 hours by using a diaphragm pump was observed. Besides, curve fitting analysis was performed in a range of 2060 to 1980 cm⁻¹ so as to separate peaks of the respective complexes. FIG. 6 illustrates both the IR spectra and curve fitting curves of the respective solutions.

As a result, it was found that in all of the rhenium complexes containing any one of the bpy ligands, a part of each complex having TEOA coordinated therein took in CO₂ contained in the passing air. Besides, 10 to 30% of all the rhenium complexes took CO₂ from the ambient air. These results reveal that a rhenium complex works as a good CO₂ absorbent. Furthermore, since a gas containing water vapor was allowed to pass, it was predicted that water was unavoidably supplied to the solution and hence generation of Re—OH and Re—OCO₂H might compete. After the ambient air was allowed to pass, however, no yellow solid was separated, and hence, it is presumed that none of these complexes were generated or their amounts was ignorably small.

It was found that CO₂ uptake efficiency is largely varied depending on a substituent contained in the bpy ligand and that the equilibrium thereof accords with Hammett rule. A positive correlation (ρ=0.8>0) was found in a Hammett plot, and it was found that the CO₂ uptake by Re-TEOA tends to more easily occur as the charge density of rhenium is smaller.

Besides, 1% CO₂ or 10% CO₂ was allowed to pass instead of the 100% CO₂ gas so as to check whether or not CO₂ could be taken in by Re-TEOA, and as a result, it was found that CO₂ was taken in at high frequency and that a similar compound, Re(bpy)(CO)₃(OCOCH₂CH₂)N(CH₂CH₂OH)₂ had been generated.

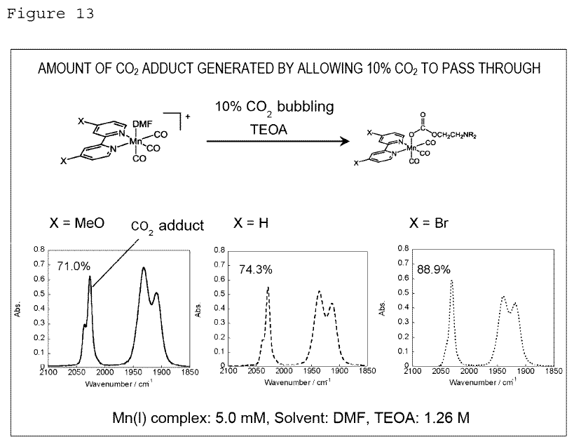

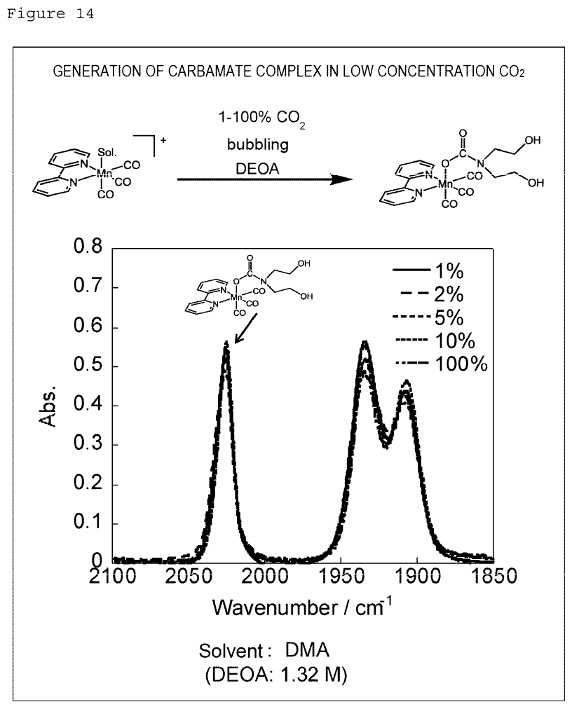

(4) Each of Mn(bpy)(CO)₃(MeCN), Mn(MeObpy)(CO)₃(MeCN) and Mn(Brbpy)(CO)₃(MeCN) was dissolved in DMF containing triethanolamine (TEOA), and CO₂ was blown thereinto, so as to examine, through FT-IR measurement, whether or not CO₂ was taken in in the same manner as in using the Re complexes (FIG. 13).

As a result, it was found that the following reactions had occurred:

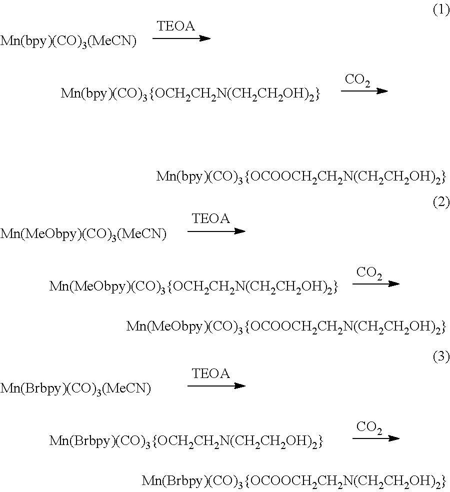

(5) Besides, it was examined whether or not CO₂ was taken in even if CO₂ at a low concentration was used. The uptake of CO₂ was examined by blowing the ambient air instead of CO₂. As a result, uptake of 21.7%, 14.7% and 37.1% of CO₂ was observed respectively in using Mn(bpy)(CO)₃{OCH₂CH₂N(CH₂CH₂OH)₂}, Mn (MeObpy)(CO)₃{OCH₂CH₂N(CH₂CH₂OH)₂}, and Mn(Brbpy)(CO)₃{OCH₂CH₂N(CH₂CH₂OH)_{2}.}

(6) Besides, 1% CO₂, 2% CO₂, 5% CO₂ or 10% CO₂ was allowed to pass through instead of 100% CO₂ gas, and the CO₂ uptake by Mn (bpy)(CO)₃(OCH₂CH₂NH(CH₂CH₂OH)₂), Mn(MeObpy)(CO)₃ (OCH₂CH₂N(CH₂CH₂OH)₂) or Mn(Brbpy)(CO)₃(OCH₂CH₂N(CH₂CH₂OH)₂) was examined. As a result, it was found, as shown in Table 1, that CO₂ was efficiently taken in.

TABLE 1

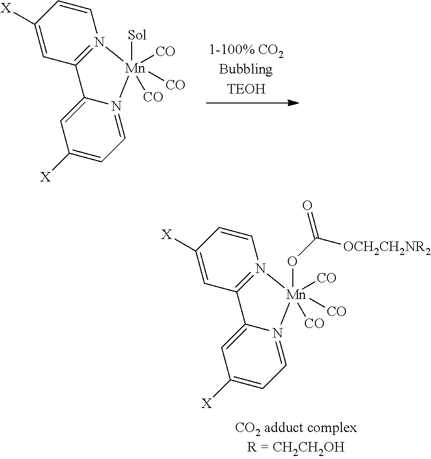

Proportion of CO₂ adduct complex generated /%

| Proportion of CO₂ gas/% | 1 | 2 | 5 | 10 |
|---|---|---|---|---|
| X = MeO | — | 55.7 | 62.4 | 71.0 |
| X = H | 54.1 | 58.2 | 65.3 | 74.3 |
| X = Br | — | 75.5 | 79.6 | 88.9 |

(7) The CO₂ uptake by a Mn complex in which another compound was coordinated instead of triethanolamine was examined.

A Mn complex (Mn(bpy)(CO)₃(CH₃CN)) was dissolved in DMF-TEA (triethylamine), and CO₂ was blown into the resultant. As a result, Mn(bpy)(CO)₃(OEt) was generated, and a CO₂ adduct of this, that is, Mn(bpy)(CO)₃OC(O)OEt, was found to be generated.

(8) The CO₂ uptake by a Mn complex in which diethanolamine (DEOA) was coordinated instead of triethanolamine was examined.

When a Mn complex was dissolved in a DMF-DEOA mixed solution and CO₂ was blown into this solution, a reaction with DEQA present in the solution was caused to generate carbamic acid, and it was found that a carbamate complex Mn (bpy)(CO)₃(OCON(CH₂CH₂OH)₂) was generated through coordination of the carbamic acid in the complex. FIG. 14 illustrates IR spectrum change of the Mn complex in DMF-DEOA under CO₂ atmosphere at various concentrations.

(9) The CO₂ uptake by a Mn complex in which diethylamine (DEA) was coordinated instead of triethanolamine was examined.

As a result, Mn(bpy)(CO)₃(DEA) was generated from Mn(bpy)(CO)₃(CH₃CN), and a CO₂ adduct of this, that is, Mn(bpy)(CO)₃(OCON(Et)₂), was confirmed to be generated.

(10) The CO₂ uptake by a Re complex in which another compound was coordinated instead of triethanolamine was examined.

DEQA (diethanolamine) was caused to work on a Re complex (Re(bpy)(CO)₃(CH₃CN) in DMF, and CO₂ was blown into the resultant. As a result, Re(bpy)(CO)₃(NH(CH₂CH₂OH)₂) was generated, and a CO₂ adduct of this, that is, Re(bpy)(CO)₃(OCON(CH₂CH₂OH)₂), was found to be generated.

(11) The CO₂ uptake by a Re complex (Re(bpy)(CO)₃(CH₃CN) in which diethylamine (DEA) was coordinated) was examined.

As a result, Re(bpy)(CO)₃(DEA) was generated from (Re(bpy)(CO)₃(CH₃CN), and a CO₂ adduct of this, that is, Re(bpy)(CO)₃(OCON(Et)₂), was confirmed to be generated.

### Test Example 1 (Generation of CO Through Electrochemical Reduction Using Re Complex)

An H-type electrochemical cell including an ion exchange membrane (Nafion-H) disposed inside as schematically illustrated in FIGS. 1 and 2 was produced. On a working electrode side, 84 mL of a DMF-TEOA (in a volume ratio of 5:1) solution containing 0.5 mM Re(4,4′-(Me)₂ (bpy)(CO)₃OCOOCH₂CH₂N(CH₂CH₂OH)₂ and 0.1 M Et₄NBF₄ was added. On the other hand, on a counter electrode side, 84 mL of a DMF-TEOA (in a volume ratio of 5:1) solution containing 0.1 M Et₄NBF₄ was added. Netted glassy carbon (glassy carbon) was used as a working electrode, a platinum cross mesh electrode was used as a counter electrode, and a silver/silver nitrate electrode was used as a reference electrode. FIG. 9 illustrates results of cyclic voltammetry measurement performed for setting an application voltage in this Test Example 1. Based on FIG. 9, a conspicuous current response was found in the vicinity of an application voltage of −2.0 V, and it is determined that a catalytic reduction reaction of CO₂ occurred at this voltage.

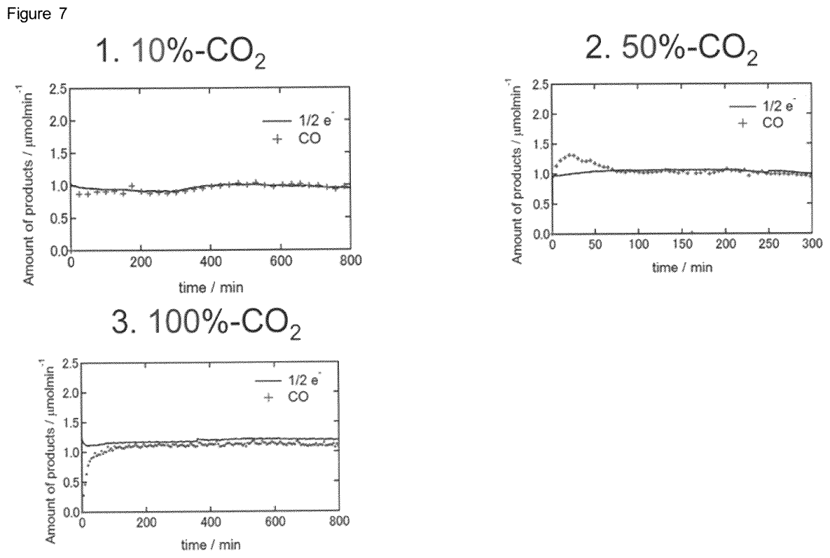

On the working electrode side, 10% CO₂, 50% CO₂ or 100% CO₂ (a component excluding CO₂ being Ar) was bubbled, and a voltage of −2.1 V (using Ag/AgNO₃ as the reference electrode) was applied. As a result, it was found, as illustrated in FIG. 7, that CO₂ was selectively reduced to CO even if the CO₂ concentration was 10%. The faradaic efficiency of the CO generation was substantially 100%.

### Test Example 2

An electrochemical cell similar to that of Test Example 1 except that the solvent DMF-TEOA used on the working electrode side was changed to DMF was produced. While bubbling 10% CO₂ gas, 7 mL of TEOA was added on the working electrode side, and change in a current at which CO was generated was observed.

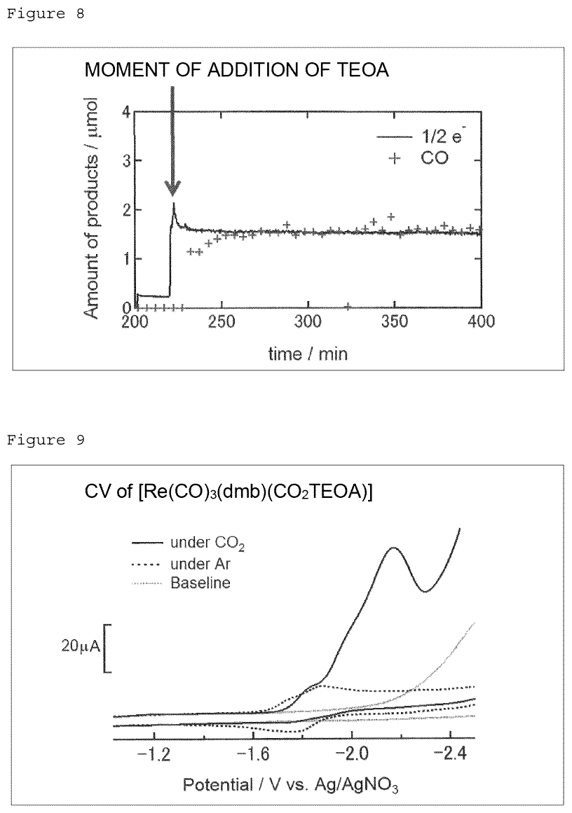

As a result, as illustrated in FIG. 8, the current value was increased by about 6 times from 0.76 mA to 4.85 mA, and it was understood that CO₂ reducing ability could be further improved by causing CO₂ addition function (by shifting the equilibrium relationship toward side of generation of a CO₂ adduct) through addition of TEOA.

### Test Example 3 (Generation of Formic Acid Through Electrochemical Reduction Using Mn Complex and TEOA)

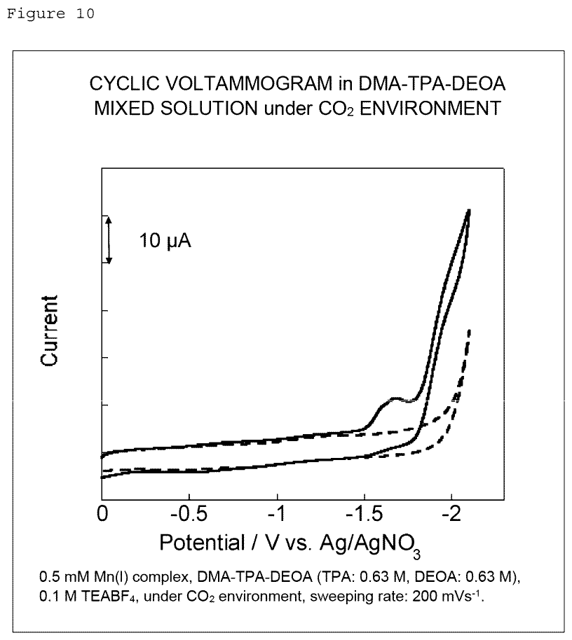

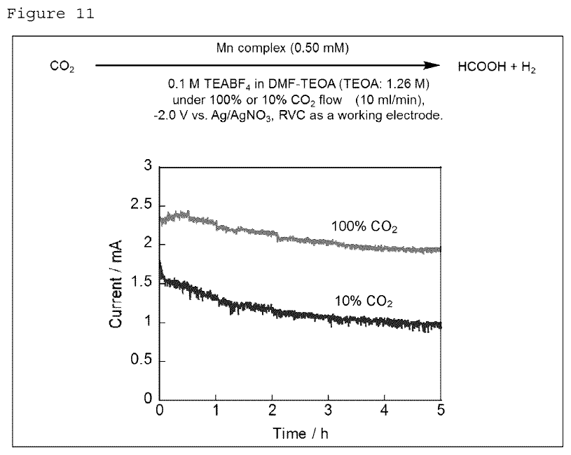

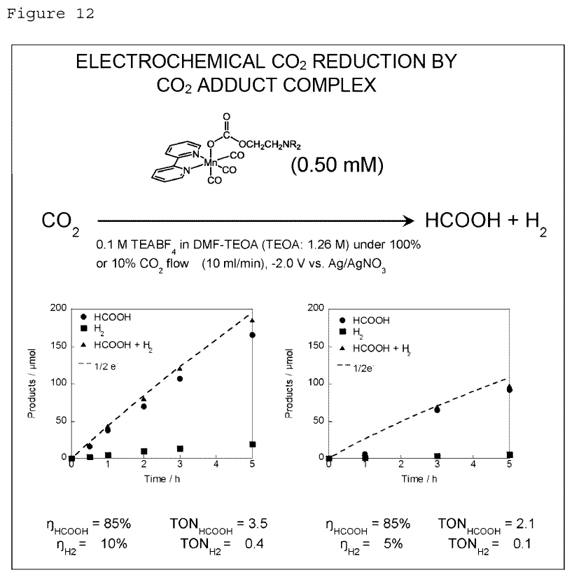

An H-type electrochemical cell including an ion exchange membrane (Nafion-H) disposed inside was produced. On a working electrode side, 84 mL of a DMF-TEOA solution (TEOA: 1.26 M) containing 0.5 mM Mn(bpy)(CO)₃OCOOCH₂CH₂N(CH₂CH₂OH)₂ and 0.1 M TEABF₄ was added. On the other hand, on a counter electrode side, 84 mL of a DMF-TEOA solution (TEOA: 1.26 M) containing 0.1 M TEABF₄ was added. Netted glassy carbon (glassy carbon) was used as a working electrode, a platinum cross mesh electrode was used as a counter electrode, and a silver/silver nitrate electrode was used as a reference electrode. FIG. 10 illustrates results of the cyclic voltammetry measurement performed for setting an application voltage in this Test Example 3. Based on FIG. 10, a conspicuous current response was found in the vicinity of an application voltage of −2.0 V, and it is determined that a catalytic reduction reaction of CO₂ occurred at this voltage.

On the working electrode side, 10% CO₂ or 100% CO₂ (a component excluding CO₂ being Ar) was bubbled, and a voltage of 2.0 V (using Ag/AgNO₃ as the reference electrode) was applied. As a result, it was found, as illustrated in FIGS. 12 and 13, that formic acid was selectively generated even if the CO₂ concentration was 10%.

### Test Example 4 (Generation of Formic Acid Through Electrochemical Reduction Using Mn Complex and DEQA)

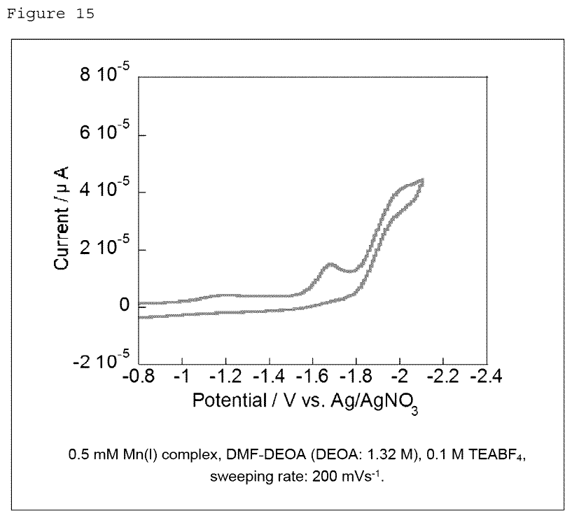

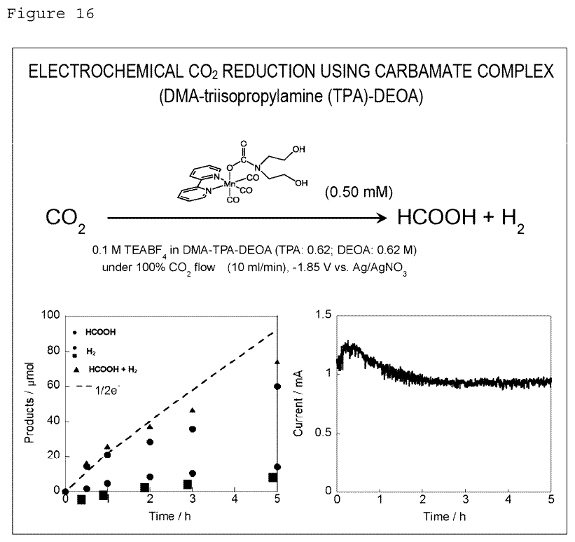

An H-type electrochemical cell including an ion exchange membrane (Nafion-H) disposed inside was produced. On a working electrode side, 95 mL of a DMF solution containing 0.5 mM Mn (bpy)(CO)₃ (OCONCH₂CH₂NR₂) (R=CH₂CH₂OH), 0.1 M Et₄NBF₄, 0.62 M DEOA and 0.62 M tripropylamine was added. On a counter electrode side, 95 mL of a DMF solution containing 0.1 M Et₄NBF₄, 0.62 M DEOA and 0.62 M tripropylamine was added. Netted glassy carbon was used as a working electrode, a platinum mesh electrode was used as a counter electrode, and a silver/silver nitrate electrode was used as a reference electrode. FIG. 15 illustrates results of the cyclic voltammetry measurement performed for setting an application voltage in this Test Example 4. Based on FIG. 15, a conspicuous current response was found in the vicinity of an application voltage of −1.85 V, and it is determined that a catalytic reduction reaction of CO₂ occurred at this voltage.

While bubbling CO₂ gas on the working electrode side, a voltage of −1.85 V (using Ag/AgNO₃ as the reference electrode) was applied. As a result, it was found that CO₂ was highly selectively reduced to HCOOH.

1: An electrochemical cell comprising a solution containing a metal complex, a working electrode and a counter electrode, wherein the metal complex is represented by formula (2a): 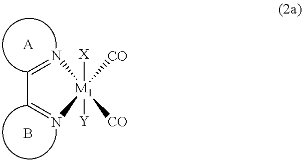
wherein M₁ represents manganese, ruthenium or iron,
X represents O(CH₂)ₙNR⁵R⁶, NR⁵R⁶ or PX¹X²X³,
Y represents CO, C(CH₂)ₙNR⁵R⁶, NR⁵R⁶ or PX¹X²X³,
ring A and ring B are identical or different and represent a nitrogen atom-containing heterocycle optionally having a substituent,
one, two or three of X¹, X² and X³ are identical or different and represent a hydrocarbon group optionally having a substituent or a hydrocarbon oxy group optionally having a substituent, the rest representing a hydrogen atom or a hydroxy group,
R⁵ and R⁶ are identical or different and represent an alkyl group, a hydroxyalkyl group or a hydrogen atom, and
n represents a number of 2 to 8.

2: The electrochemical cell according to claim 1, wherein the solution containing a metal complex is a protic polar solvent.

3: The electrochemical cell according to claim 2, wherein the protic polar solvent is water, an alcohol-based solvent, an amine-based solvent, a thiol-based solvent or an amino alcohol-based solvent.

4: A carbon monoxide production system for producing carbon monoxide by electrochemically reducing carbon dioxide, comprising:
the electrochemical cell as defined in claim 1 as an electrochemical cell part;
an injection part through which carbon dioxide is injected into the solution containing the metal complex held in the electrochemical cell part;
a voltage source capable of applying a positive or negative voltage between the working electrode and the counter electrode of the electrochemical cell part; and
a discharge part discharging carbon monoxide generated within the solution containing the metal complex,
wherein the carbon monoxide is generated by applying a positive or negative voltage to a reaction product of the metal complex generated by the solution containing the metal complex and the carbon dioxide.

5: The carbon monoxide production system according to claim 4, wherein the carbon dioxide is fed without concentration in a feed part feeding the carbon dioxide.

6: The carbon monoxide production system according to claim 4, further comprising a carbon monoxide detection part detecting a concentration of the carbon monoxide discharged from the solution containing the metal complex.

7: The carbon monoxide production system according to claim 4, wherein the carbon monoxide detection part is a gas chromatography.

8: A method for producing carbon monoxide, which comprises reducing carbon dioxide by the system as defined in claim 4.
